(19) United States
(12) Patent Application Publication
(10) Pub. No.: US 2021/0293489 A1
(43) Pub. Date: Sep. 23, 2021

(54) HEAT STORAGE SHEET, HEAT STORAGE MEMBER, AND ELECTRONIC DEVICE

(71) Applicant: FUJIFILM Corporation, Tokyo (JP)

(72) Inventors: Tetsuro MITSUI, Shizuoka (JP); Naotoshi SATO, Shizuoka (JP); Miyoko HARA, Shizuoka (JP); Masahiro HATTA, Shizuoka (JP); Hirokazu KITO, Shizuoka (JP); Hiroshi KAWAKAMI, Shizuoka (JP); Aya NAKAYAMA, Shizuoka (JP); Takuto MATSUSHITA, Shizuoka (JP); Kyohei OGAWA, Shizuoka (JP)

(73) Assignee: FUJIFILM Corporation, Tokyo (JP)

(21) Appl. No.: 17/313,008

(22) Filed: May 6, 2021

Related U.S. Application Data
(63) Continuation of application No. PCT/JP2019/043865, filed on Nov. 8, 2019.

(30) Foreign Application Priority Data
Nov. 26, 2018 (JP) 2018-220569
Feb. 28, 2019 (JP) 2019-036983
Mar. 25, 2019 (JP) 2019-057347
Jun. 28, 2019 (JP) 2019-122065
Aug. 30, 2019 (JP) 2019-158766
Sep. 2, 2019 (JP) 2019-159485
Oct. 7, 2019 (JP) 2019-184716

(51) Int. Cl. F28D 20/02

(52) U.S. Cl. CPC F28D 20/023; F28D 2020/0008

(57) ABSTRACT

An object of the present invention is to provide a heat storage sheet in which the occurrence of defects when handling it is suppressed, and a heat storage member and an electronic device including the heat storage sheet.

The heat storage sheet according to an embodiment of the present invention includes a microcapsule which encapsulates a heat storage material, in which a void volume is less than 10% by volume.

### CROSS-REFERENCE TO RELATED APPLICATIONS

This application is a Continuation of PCT International Application No. PCT/JP2019/043865 filed on Nov. 8, 2019, which claims priority under 35 U.S.C. § 119(a) to Japanese Patent Application No. 2018-220569 filed on Nov. 26, 2018, Japanese Patent Application No. 2019-036983 filed on Feb. 28, 2019, Japanese Patent Application No. 2019-057347 filed on Mar. 25, 2019, Japanese Patent Application No. 2019-159485 filed on Sep. 2, 2019, Japanese Patent Application No. 2019-122065 filed on Jun. 28, 2019, Japanese Patent Application No. 2019-158766 filed on Aug. 30, 2019, and Japanese Patent Application No. 2019-184716 filed on Oct. 7, 2019. Each of the above applications is hereby expressly incorporated by reference, in its entirety, into the present application.

### BACKGROUND OF THE INVENTION

### 1. Field of the Invention

The present invention relates to a heat storage sheet, a heat storage member, and an electronic device.

### 2. Description of the Related Art

In recent years, a microcapsule which encapsulates functional materials such as a heat storage material, a fragrance, a dye, and a pharmaceutical component has attracted attention.

For example, a microcapsule which encapsulates a phase change material (PCM) such as paraffins or the like has been known. Specifically, WO2015/059855A discloses a heat storage sheet including a microcapsule in which paraffin, which is a heat storage material, is encapsulated by a capsule wall formed of a formalin resin, and the formalin resin, and has a void volume of 10% to 30% by volume.

### SUMMARY OF THE INVENTION

The present inventors have evaluated the heat storage sheet including the microcapsule which encapsulates the heat storage material as disclosed in WO2015/059855A, it has been found that there is a case in which defects (for example, cracks and breaks) occur in the heat storage sheet when handling it.

In view of the above circumstances, an object of the present invention is to provide a heat storage sheet in which the occurrence of defects when handling it is suppressed, and a heat storage member and an electronic device including the heat storage sheet.

As a result of diligent studies on the above objects, the present inventors have found that the above objects can be solved by the configurations as follows.

[1] A heat storage sheet comprising a microcapsule which encapsulates a heat storage material, in which a void volume is less than 10% by volume.

[2] The heat storage sheet according to [1], in which the void volume is 5% by volume or less.

[3] The heat storage sheet according to [1] or [2], in which an adjacency ratio of the microcapsule is 80% or more.

[4] A heat storage sheet comprising a microcapsule which encapsulates a heat storage material, in which an adjacency ratio of the microcapsule is 80% or more.

[5] The heat storage sheet according to any one of [1] to [4], in which the heat storage material includes a linear aliphatic hydrocarbon, and a content of the linear aliphatic hydrocarbon to a total mass of the heat storage material is 98% by mass or more.

[6] The heat storage sheet according to any one of [1] to [5], in which a content of the heat storage material to a total mass of the heat storage sheet is 50% by mass or more.

[7] The heat storage sheet according to any one of [1] to [6], in which a capsule wall of the microcapsule is formed of polyurethane urea.

[8] The heat storage sheet according to any one of [1] to [7], in which a ratio of a thickness of a capsule wall of the microcapsule to a volume-based median diameter of the microcapsule is 0.0075 or less.

[9] The heat storage sheet according to any one of [1] to [8], in which a thickness of a capsule wall of the microcapsule is 0.15 μm or less.

[10] The heat storage sheet according to any one of [1] to [9], in which a deformation rate of the microcapsule is 35% or more.

[11] The heat storage sheet according to any one of [1] to [10], in which a content of water to a total mass of the heat storage sheet is 5% by mass or less.

[12] The heat storage sheet according to any one of [1] to [11], further comprising a binder.

[13] The heat storage sheet according to [12], in which the binder includes a water-soluble polymer, and a content of the water-soluble polymer to a total mass of the binder is 90% by mass or more.

[14] The heat storage sheet according to [13], in which the water-soluble polymer is polyvinyl alcohol.

[15] The heat storage sheet according to [14], in which the polyvinyl alcohol has a modified group.

[16] The heat storage sheet according to [15], in which the modified group is at least one group selected from the group consisting of a carboxy group or a salt thereof and an acetoacetyl group.

[17] A heat storage member comprising the heat storage sheet according to any one of [1] to [16].

[18] The heat storage member according to [17], further comprising a base material which is disposed on the heat storage sheet, an adhesion layer which is disposed on a surface side of the base material opposite to the heat storage sheet, and a temporary base material which is disposed on a surface side of the adhesion layer opposite to the base material.

[19] An electronic device comprising the heat storage member according to claim [17] or [18], and a heat generating body.

[20] The electronic device according to [19], further comprising a member selected from the group consisting of a heat pipe and a vapor chamber.

According to the present invention, it is possible to provide a heat storage sheet in which the occurrence of defects when handling it is suppressed, and a heat storage member and an electronic device including the heat storage sheet.

### DESCRIPTION OF THE PREFERRED EMBODIMENTS

The present invention will be described below in detail.

Note that in the present specification, the numerical range represented by using “to” means a range including numerical values denoted before and after “to” as a lower limit value and an upper limit value.

Various components which will be described below may be used alone or in the combination of two types or more. For example, polyisocyanate which will be described below may be used alone or in the combination of two types or more.

### Heat Storage Sheet (First Embodiment)

A heat storage sheet according to a first embodiment of the present invention includes a microcapsule which encapsulates a heat storage material, in which a void volume is less than 10% by volume.

With the heat storage sheet according to the first embodiment, the occurrence of defects when handling it can be suppressed. It is presumed that the improvement is due to the following reasons.

In a case in which the void volume of the heat storage sheet is low, it is considered that a contact area between the microcapsules in the heat storage sheet becomes large, so that the strength of the heat storage sheet is improved. As a result, it is presumed that the brittleness of the heat storage sheet is increased and the occurrence of defects (for example, cracks and breaks) when handling it of the heat storage sheet can be suppressed.

<Microcapsule>

The microcapsule has a core portion and a capsule wall for encapsulating a core material (encapsulated material (also referred to as an encapsulating component)) which forms the core portion.

The microcapsule encapsulates the heat storage material as the core material (encapsulating component). Since the heat storage material is encapsulated in the microcapsule, the heat storage material can be stably present in a phase state depending on the temperature.

(Heat Storage Material)

The type of heat storage material is not particularly limited, and a material in which a phase change occurs depending on a temperature change can be used, and it is preferably a material in which the phase change between the solid phase and the liquid phase can be repeated with a state change of melting and solidification depending on the temperature change.

It is preferable that the phase change of the heat storage material be based on the phase change temperature of the heat storage material itself, and in the case of the phase change between the solid phase and the liquid phase, it is preferably based on a melting point.

As the heat storage material, for example, any of a material which can store heat which is generated outside the heat storage sheet as sensible heat or a material (hereinafter, also referred to as “latent heat storage material”) which can store heat which is generated outside the heat storage sheet as latent heat, or a material in which a phase change occurs due to a reversible chemical change may be adopted. The heat storage material is preferably a material which can radiate the stored heat.

Among these, it is preferable that the heat storage material be the latent heat storage material, from the viewpoint of the ease of the control of the amount of heat which can be transferred, and the magnitude of the amount of heat.

The latent heat storage material means a material which stores heat, which is generated outside the heat storage sheet, as latent heat. For example, it refers to a material which transfers heat due to latent heat by repeating the change between melting and solidification with the melting point determined by the material as a phase change temperature in a case of the phase change between the solid phase and the liquid phase.

In a case of the phase change between the solid phase and the liquid phase, the latent heat storage material can utilize the heat of fusion at the melting point and the heat of solidification at a solidifying point, store heat depending on the phase change between the solid phase and the liquid phase, and radiate heat.

The type of the latent heat storage material is not particularly limited, and it can be selected from compounds having a melting point and capable of changing a phase.

Examples of the latent heat storage material include ice (water); an inorganic salt; an aliphatic hydrocarbon such as paraffin (for example, isoparaffin and normal paraffin) and the like; a fatty acid ester compound such as caprylic/capric triglyceride, methyl myristate (melting point of 16° C. to 19° C.), isopropyl myristate (melting point of 167° C.), and dibutyl phthalate (melting point of −35° C.); an aromatic hydrocarbon such as an alkylnaphthalene compound such as diisopropylnaphthalene (melting point of 67° C. to 70° C.), a diarylalkane compound such as 1-phenyl-1-xylylethane (melting point lower than −50° C.), an alkylbiphenyl compound such as 4-isopropylbiphenyl (melting point of 11° C.), a triarylmethane compound, an alkylbenzene compound, a benzylnaphthalene compound, a diarylalkylene compound, and an aryl indane compound; natural animal and plant oils such as camellia oil, soybean oil, corn oil, cotton seed oil, rapeseed oil, olive oil, coconut oil, castor oil, and fish oil; mineral oil; diethyl ethers; aliphatic diol; sugar; and sugar alcohol.

The phase change temperature of the heat storage material is not particularly limited, and it need only be appropriately selected depending on the type of the heat generating body which generates heat, a heat generating temperature of the heat generating body, a temperature or a maintaining temperature after cooling, a cooling method, and the like.

It is preferable that a material which has the phase change temperature (preferably, a melting point) at a target temperature range (for example, an operating temperature of the heat generating body; hereinafter, also referred to as a “heat control range”) be selected as the heat storage material.

The phase change temperature of the heat storage material differs depending on the heat control range, but it is preferably 0° C. to 80° C., and more preferably 10° C. to 70° C.

As the heat storage material, from the viewpoint of application to an electronic device (in particular, a small or portable electronic device), the heat storage material having the following melting points is preferable.

(1) As the heat storage material (preferably, the latent heat storage material), the heat storage material having the melting point of 0° C. to 80° C. is preferable.

In a case in which the heat storage material having the melting point of 0° C. to 80° C. is used, the material having the melting point lower than 0° C. or higher than 80° C. is not included in the heat storage material. Among the materials having the melting point lower than 0° C. or higher than 80° C., the material in the liquid state may be used in combination with the heat storage material as a solvent.

(2) In the above (1), the heat storage material having the melting point of 10° C. to 70° C. is preferable.

In a case in which the heat storage material having the melting point of 10° C. to 70° C. is used, the material having the melting point lower than 10° C. or higher than 70° C. is not included in the heat storage material. Among the materials having the melting point lower than 10° C. or higher than 70° C., the material in the liquid state may be used in combination with the heat storage material as a solvent.

(3) Further, among the above (2), the heat storage material having the melting point of 15° C. to 50° C. is preferable.

In a case in which the heat storage material having the melting point of 15° C. to 50° C. is used, the material having the melting point lower than 15° C. or higher than 50° C. is not included in the heat storage material. Among the materials having the melting point lower than 15° C. or higher than 50° C., the material in the liquid state may be used in combination with the heat storage material as a solvent.

(4) Further, in the above (2), the heat storage material having the melting point of 20° C. to 62° C. is also preferable.

In particular, the heat generating body of the electronic device, such as a thin or portable laptop computer, a tablet, and a smartphone, has the operating temperature of 20° C. to 65° C. in many cases, and it is suitable to use the heat storage material having the melting point of 20° C. to 62° C. In a case in which the heat storage material having the melting point of 20° C. to 62° C. is used, the material having the melting point lower than 20° C. or higher than 62° C. is not included in the heat storage material. Among the materials having the melting point lower than 20° C. or higher than 62° C., the material in the liquid state may be used in combination with the heat storage material as the solvent, but it is preferable that the solvent be substantially excluded in terms of absorbing a large amount of heat which is generated by the heat generating body.

Above all, from the viewpoints of having more excellent heat storage property of the heat storage member, being capable of reducing the void volume of the capsule, and being capable of increasing the capsule adjacency ratio, an aliphatic hydrocarbon is preferable as the latent heat storage material, and paraffin is more preferable.

The melting point of the aliphatic hydrocarbon (preferably, paraffin) is not particularly limited, but from the viewpoint of application of the heat storage member to various uses, it is preferably 0° C. or higher, more preferably 15° C. or higher, and further preferably 20° C. or higher. The upper limit is not particularly limited, but it is preferably 80° C. or lower, more preferably 70° C. or lower, further preferably 60° C. or lower, and particularly preferably 50° C. or lower.

As the aliphatic hydrocarbon, a linear aliphatic hydrocarbon is preferable from the viewpoint of having a more excellent heat storage property of the heat storage member. The number of carbon atoms of the linear aliphatic hydrocarbon are not particularly limited, but are preferably 14 or more, more preferably 16 or more, and further preferably 17 or more. The upper limit is not particularly limited, but it is preferably 26 or less.

As the aliphatic hydrocarbon, linear aliphatic hydrocarbon having a melting point of 0° C. or higher is preferable, and linear aliphatic hydrocarbon having a melting point of 0° C. or higher and having 14 or more carbon atoms is more preferable.

Examples of the linear aliphatic hydrocarbon (linear paraffin) having the melting point of 0° C. or higher include n-tetradecane (melting point of 6° C.), n-pentadecane (melting point of 10° C.), n-hexadecane (melting point of 18° C.), n-heptadecane (melting point of 22° C.), n-octadecane (melting point of 28° C.), n-nonadecane (melting point of 32° C.), n-icosane (melting point of 37° C.), n-henicosane (melting point of 40° C.), n-docosane (melting point of 44° C.), n-tricosane (melting point of 48° C. to 50° C.), n-tetracosane (melting point of 52° C.), n-pentacosane (melting point of 53° C. to 56° C.), n-hexacosane (melting point of 57° C.), n-heptacosane (melting point of 60° C.), n-octacosane (melting point of 62° C.), n-nonacosane (melting point of 63° C. to 66° C.), and n-triacontane (melting point of 66° C.).

Among these, n-heptadecane (melting point of 22° C.), n-octadecane (melting point of 28° C.), n-nonadecane (melting point of 32° C.), n-icosane (melting point of 37° C.), n-henicosane (melting point of 40° C.), n-docosane (melting point of 44° C.), n-tricosane (melting point of 48° C. to 50° C.), n-tetracosane (melting point of 52° C.), n-pentacosane (melting point of 53° C. to 56° C.), n-hexacosane (melting point of 60° C.), n-heptacosane (melting point of 60° C.), or n-octacosane (melting point of 62° C.) is preferably used.

In a case in which linear aliphatic hydrocarbon is used as the heat storage material, the content of the linear aliphatic hydrocarbon to the content of the heat storage material is preferably 80% by mass or more, more preferably 90% by mass or more, further preferably 95% by mass or more, and particularly preferably 98% by mass or more. For example, an upper limit is 100% by mass.

As the inorganic salt, an inorganic hydrated salt is preferable, and the examples thereof include alkali metal chloride hydrate (for example, sodium chloride dihydrate), alkali metal acetate hydrate (for example, sodium acetate hydrate), alkali metal sulfate hydrate (for example, sodium sulfate hydrate), alkali metal thiosulfate hydrate (for example, sodium thiosulfate hydrate), alkaline earth metal sulfate hydrate (for example, calcium sulfate hydrate), and alkaline earth metal chloride hydrate (for example, calcium chloride hydrate).

As an example of the aliphatic diol, there are 1,6-hexanediol and 1,8-octanediol.

As an example of the sugar and sugar alcohol, there are xylitol, erythritol, galactitol, and dihydroxyacetone.

The heat storage material may be used alone, or may be used in the combination of two types or more. By using the heat storage material alone or a plurality of types of heat storage materials having different melting points, it is possible to adjust the temperature range in which the heat storage property is exhibited and the amount of heat storage depending on the application.

The temperature range in which heat can be stored can be widened by mixing the heat storage material, as a center material, having the melting point at the center temperature at which the heat storage effect of the heat storage material is desired, and the heat storage material having the melting point before and after the center temperature. An example of a case in which the paraffin is used as the heat storage material will be specifically described. Paraffin a having the melting point at the center temperature at which the heat storage effect of the heat storage material is desired is used as a center material, and the paraffin a and another paraffin which has the carbon atoms before and after the paraffin a are mixed, so that the design can be made such that the heat storage sheet has a wide temperature range (heat control range).

The content of paraffin having the melting point at the center temperature at which the heat storage effect is desired is not particularly limited, but it is preferably 80% by mass or more, more preferably 90% by mass or more, further preferably 95% by mass or more, and particularly preferably 98% by mass or more, based on the total mass of the heat storage material. For example, an upper limit is 100% by mass.

In a case in which the paraffin is used as the heat storage material, for example, the paraffin may be used alone or may be used in the combination of two types or more. In a case in which a plurality of paraffins which have different melting points are used, the temperature range in which the heat storage property is exhibited can be widened. In a case in which the plurality of paraffins which have different melting points are used, a mixture including only linear paraffin and substantially excluding branched chain paraffin is desirable in order not to reduce the endothermic property. Where, substantially excluding the branched chain paraffin means that the content of the branched chain paraffin to the total mass of the paraffin is 5% by mass or less, and it is preferably 2% by mass or less, and further preferably 1% by mass or less.

On the other hand, as the heat storage material which is to apply to the electronic device, it is also preferable that there be substantially one paraffin. In a case in which there is substantially one paraffin, the heat storage sheet is filled with paraffin with the high purity, so that the endothermic property of the electronic device with respect to the heat generating body is good. Where, substantially one paraffin means that the content of the main paraffin to the total mass of the paraffin is 95% to 100% by mass, and it is preferably 98% to 100% by mass.

In a case in which the plurality of paraffins are used, from the viewpoints of the temperature range in which the heat storage property is exhibited and the amount of heat storage, the content of the main paraffin is not particularly limited, but it is preferably 80% by mass to 100% by mass, more preferably 90% by mass to 100% by mass, and further preferably 95% by mass to 100% by mass, based on the total mass of the paraffin.

The “main paraffin” refers to the paraffin having the largest content among the plurality of paraffins which are contained. It is preferable that the content of the main paraffin to the total mass of the paraffin be 50% by mass or more.

The content of paraffin is not particularly limited, but it is preferably 80% to 100% by mass, more preferably 90% to 100% by mass, further preferably 95% to 100% by mass, and particularly preferably 98% to 100% by mass, based on the total mass of the heat storage material (preferably, the latent heat storage material).

Further, as the paraffin, linear paraffin is preferable, and it is preferable that branched chain paraffin be substantially excluded. This is because the heat storage property is further improved by including the linear paraffin and substantially excluding the branched chain paraffin. It is presumed that the reason is that the association of linear paraffin molecules with each other can be suppressed from being inhibited by branched chain paraffin.

The content of the heat storage material in the heat storage sheet is not particularly limited, but from the viewpoint of more excellent heat storage property of the heat storage member, it is preferably 50% by mass or more, more preferably 65% by mass or more, further preferably 75% by mass or more, and particularly preferably 80% by mass or more, based on the total mass of the heat storage sheet. The upper limit of the content of the heat storage material is not particularly limited, but it is preferably 99.9% by mass or less, more preferably 99% by mass or less, and further preferably 98% by mass based on the total mass of the heat storage sheet, from the viewpoint of more excellent heat storage property of the heat storage sheet.

(Other Components)

As the core material of the microcapsule, components other than the heat storage material described above may be encapsulated. Examples of other components which can be encapsulated in the microcapsule as the core material include the solvent, and an additive such as the flame retardant.

The content of the heat storage material in the core material is not particularly limited, but it is preferably 80% to 100% by mass, and more preferably 90% to 100% by mass, based on the total mass of the core material, from the viewpoint of more excellent heat storage property of the heat storage sheet.

The microcapsule may encapsulate the solvent as the core material.

As an example of the solvent in this case, there is the heat storage material described above of which melting point is outside the temperature range in which the heat storage sheet is used (heat control range; for example, the operating temperature of the heat generating body). That is, the solvent refers to a solvent which does not change the phase in the liquid state in the heat control range, and is distinguished from the heat storage material which undergoes a phase transition in the heat control range to cause an endothermic reaction or a heat dissipation reaction.

The content of the solvent in the core material is not particularly limited, but it is preferably less than 30% by mass, more preferably less than 10% by mass, and further preferably 1% by mass or less, based on the total mass of the core material. The lower limit is not particularly limited, but 0% by mass can be adopted, for example.

Examples of other components which may be encapsulated as the core material in the microcapsule include additives such as an ultraviolet absorbing agent, a light stabilizer, an antioxidant, a wax, and an odor suppressant.

(Capsule Wall (Wall Portion))

The microcapsule includes the capsule wall which encapsulates the core material.

The material which forms the capsule wall in the microcapsule is not particularly limited, for example, the polymer may be used, and more specific examples thereof include polyurethane urea, polyurethane, polyurea, a melamine resin, and an acrylic resin.

From the viewpoints of capable of thinning the capsule wall and more excellent heat storage property of the heat storage member, the capsule wall preferably includes polyurethane urea, polyurethane, polyurea, or a melamine resin, and more preferably includes polyurethane urea, polyurethane, or polyurea.

Polyurethane is a polymer which has a plurality of urethane bonds, and it is preferably a reaction product of polyol and polyisocyanate.

Further, polyurea is a polymer which has a plurality of urea bonds, and it is preferably a reaction product of polyamine and polyisocyanate.

Further, polyurethane urea is a polymer which has the urethane bond and the urea bond, and it is preferably a reaction product of polyol, polyamine, and polyisocyanate. In a case in which polyol and polyisocyanate are reacted with each other, a part of polyisocyanate reacts with water to form polyamine, and as a result, polyurethane urea may be obtained.

It is preferable that the capsule wall of the microcapsule have a urethane bond. The capsule wall which has the urethane bond is obtained by, for example, using polyurethane urea or polyurethane described above.

The urethane bond is a highly motile bond, and it can provide the thermoplasticity to the capsule wall. Further, it is easy to adjust the flexibility of the capsule wall. Therefore, for example, in a case in which the drying time in a case of manufacturing the heat storage sheet is lengthened, the microcapsules are easily deformed and bonded to each other. As a result, the microcapsule can easily form a closely filled structure, so that the void volume of the heat storage sheet can be further decreased and/or the adjacency ratio of the microcapsule which will be described below can be further increased.

Further, it is preferable that the microcapsule be present as a deformable particle.

In a case in which the microcapsule is the deformable particle, the microcapsule can be deformed without breaking, and a filling rate of the microcapsule in the heat storage sheet can be improved. As a result, it is possible to increase the amount of the heat storage material in the heat storage sheet, and more excellent heat storage property can be realized.

Deformation of microcapsule without breaking means the deformation from the shape in a state in which no external pressure is applied to individual microcapsules, regardless of the degree of deformation. The deformation which occurs in the microcapsule includes deformation in which spherical surfaces come into contact with each other to form a contact surface which has a flat shape, or has a convex shape of one surface and a recess shape of the other surface in a case in which the microcapsules are pressed against each other in the heat storage sheet.

From the viewpoint of the microcapsule capable of being a deformable particle, a material which forms the capsule wall is preferably polyurethane urea, polyurethane, or polyurea, more preferably polyurethane urea or polyurethane, and further preferably polyurethane urea.

As described above, it is preferable that polyurethane, polyurea, and polyurethane urea be formed by using polyisocyanate.

Polyisocyanate is a compound which has two or more isocyanate groups, and examples thereof include aromatic polyisocyanate and aliphatic polyisocyanate.

Examples of the aromatic polyisocyanate include m-phenylene diisocyanate, p-phenylene diisocyanate, 2,6-tolylene diisocyanate, 2,4-tolylene diisocyanate, naphthalene-1,4-diisocyanate, diphenylmethane-4,4′-diisocyanate, 3,3′-dimethoxy-biphenyldiisocyanate, 3,3′-dimethyldiphenylmethane-4,4′-diisocyanate, xylylene-1,4-diisocyanate, xylylene-1,3-diisocyanate, 4-chloroxylylene-1,3-diisocyanate, 2-methylxylylene-1,3-diisocyanate, 4,4′-diphenylpropane diisocyanate, and 4,4′-diphenylhexafluoropropane diisocyanate.

Examples of the aliphatic polyisocyanate include trimethylene diisocyanate, hexamethylene diisocyanate, propylene-1,2-diisocyanate, butylene-1,2-diisocyanate, cyclohexylene-1,2-diisocyanate, cyclohexylene-1,3-diisocyanate, cyclohexylene-1,4-diisocyanate, dicyclohexylmethane-4,4′-diisocyanate, 1,4-bis(isocyanatemethyl)cyclohexane, 1,3-bis(isocyanatemethyl)cyclohexane, isophorone diisocyanate, lysine diisocyanate, and hydrogenated xylylene diisocyanate.

In the above, bifunctional aromatic polyisocyanate and aliphatic polyisocyanate are described as an example, but examples of the polyisocyanate also include trifunctional or more functional polyisocyanate (for example, trifunctional triisocyanate and tetrafunctional tetraisocyanate).

More specifically, examples of the polyisocyanate also include a burette or isocyanurate, which is a trimer of the above bifunctional polyisocyanate, an adduct of polyol such as trimethylolpropane and the bifunctional polyisocyanate, formalin condensate of benzene isocyanate, polyisocyanate which has the polymerizable group such as methacryloyloxyethyl isocyanate, lysine triisocyanate, and the like.

Polyisocyanate is described in the “Polyurethane resin handbook” (edited by Keiji Iwata, published by Nikkan Kogyo Shimbun (1987)).

Among these, as polyisocyanate, trifunctional or more functional polyisocyanate is preferable.

Examples of the trifunctional or more functional polyisocyanate include trifunctional or more functional aromatic polyisocyanate, and trifunctional or more functional aliphatic polyisocyanate.

As the trifunctional or more functional polyisocyanate, trifunctional or more functional polyisocyanate (adduct type trifunctional or more functional polyisocyanate) which is an adduct (adduct) of bifunctional polyisocyanate and a compound (for example, trifunctional or more functional polyol, polyamine, or polythiol) which has three or more active hydrogen groups in the molecule, and a trimer (biuret type or isocyanurate type) of bifunctional polyisocyanate are also preferable.

Examples of the adduct type trifunctional or more functional polyisocyanate include Takenate (registered trademark) D-102, D-103, D-103H, D-103M2, P49-75S, D-110N, D-120N, D-140N, D-160N (which are manufactured by Mitsui Chemicals, Inc.), Desmodur (registered trademark) L75, UL57SP (manufactured by Sumika Bayer Urethane Co., Ltd.), Coronate (registered trademark) HL, HX, L (manufactured by Nippon Polyurethane Industry Co., Ltd.), P301-75E (manufactured by Asahi Kasei Corporation), and Burnock (registered trademark) D-750 (manufactured by DIC Corporation).

Among these, as the adduct type trifunctional or more functional polyisocyanate, Takenate (registered trademark) D-110N, D-120N, D-140N, D-160N manufactured by Mitsui Chemicals, Inc., or Burnock (registered trademark) D-750 manufactured by DIC Corporation is preferable.

Examples of the isocyanurate type trifunctional or more functional polyisocyanate include Takenate (registered trademark) D-127N, D-170N, D-170HN, D-172N, D-177N, D-204 (manufactured by Mitsui Chemicals, Inc.), Sumijour N3300 and Desmodur (registered trademark) N3600, N3900, Z4470BA (manufactured by Sumika Bayer Urethane Co., Ltd.), Coronate (registered trademark) HX, HK (manufactured by Nippon Polyurethane Industry Co., Ltd.), and Duranate (registered trademark) TPA-100, TKA-100, TSA-100, TSS-100, TLA-100, TSE-100 (manufactured by Asahi Kasei Corporation).

Examples of the biuret type trifunctional or more functional polyisocyanate include Takenate (registered trademark) D-165N, NP1100 (manufactured by Mitsui Chemicals, Inc.), Desmodur (registered trademark) N3200 (manufactured by Sumika Bayer Urethane Co., Ltd.), and Duranate (registered trademark) 24A-100 (manufactured by Asahi Kasei Corporation).

Polyol is a compound which has two or more hydroxyl groups, and examples thereof include low molecular weight polyol (for example, aliphatic polyol or aromatic polyol), polyether-based polyol, polyester-based polyol, polylactone-based polyol, castor oil-based polyol, polyolefin-based polyol, and a hydroxyl group-containing amine-based compound.

The low molecular weight polyol means polyol which has a molecular weight of 300 or less, and examples thereof include bifunctional low molecular weight polyol such as ethylene glycol, diethylene glycol, and propylene glycol, and trifunctional or more functional low molecular weight polyol such as glycerin, trimethylolpropane, hexanetriol, pentaerythritol, sorbitol, and the like.

Examples of the hydroxyl group-containing amine-based compound include amino alcohol, as an oxyalkylated derivative of the amino compound. Examples of the amino alcohol include propylene oxide or ethylene oxide adduct of the amino compound such as ethylenediamine such as N,N,N′,N′-tetrakis[2-hydroxypropyl]ethylenediamine, and N,N,N′,N′-tetrakis[2-hydroxyethyl]ethylenediamine.

Polyamine is a compound which has two or more amino groups (primary amino group or secondary amino group), and examples thereof include aliphatic polyvalent amine such as diethylenetriamine, triethylenetetramine, 1,3-propylenediamine, and hexamethylenediamine; an epoxy compound adduct of aliphatic polyvalent amine; and alicyclic polyvalent amine such as piperazine; heterocyclic diamine such as 3,9-bis-aminopropyl-2,4,8,10-tetraoxaspiro-(5,5)undecane.

The mass of the capsule wall in the microcapsule is not particularly limited, but it is preferably 12% by mass or less, and more preferably 10% by mass or less, based on the total mass of the heat storage material included in the core portion. The fact that the mass of the capsule wall to the heat storage material which is the encapsulating component is 12% by mass or less indicates that the capsule wall is a thin wall. By thinning the capsule wall, the content of the microcapsule which encapsulates the heat storage material in the heat storage sheet is increased, and as a result, the heat storage property of the heat storage member is more excellent.

The lower limit of the mass of the capsule wall is not particularly limited, but it is preferably 1% by mass or more, more preferably 2% by mass or more, and further preferably 3% by mass or more, based on the total mass of the heat storage material, from the viewpoint of maintaining the pressure resistance of the microcapsule.

(Physical Property of Microcapsule)

—Particle Diameter—

The particle diameter of the microcapsule is not particularly limited, but the volume-based median diameter (Dm) is preferably 1 to 80 μm, more preferably 10 to 70 μm, and further preferably 15 to 50 μm. As the particle diameter of the microcapsule is smaller, the void between the microcapsules can be reduced, and the contact area between the microcapsules can be widened, so that the occurrence of defects when handling it can be further suppressed. From such a viewpoint, the particle diameter of the microcapsule is, in terms of the volume-based median diameter (Dm), preferably 40 μm or less, more preferably 30 vim or less, further preferably 20 vim or less, and particularly preferably 19 vim or less.

The volume-based median diameter of the microcapsule can be controlled by changing the dispersion conditions in the emulsification step of the method, which will be described below for the manufacturing method of the microcapsule.

Where, the volume-based median diameter of the microcapsule is a particle diameter at which the total volume of particles on a large diameter side and a small diameter side is equal in a case in which the entire microcapsule is divided into two with the particle diameter as a threshold value. The volume-based median diameter of microcapsule is measured by a laser diffraction/light scattering method using Microtrac MT3300EXII (manufactured by Nikkiso Co., Ltd.).

In a separating method of the microcapsule, the heat storage sheet is immersed in water for 24 hours or longer, and the obtained water dispersion liquid is centrifuged to obtain the isolated microcapsule.

—Particle Diameter Distribution—

The particle diameter distribution of the microcapsule is not particularly limited, but it is preferable that the coefficient of variation (CV) value (correlation coefficient) of the volume-based median diameter of the microcapsule calculated by the following equation be 10% to 100%.

CV value=standard deviation 6/median diameter×100 The standard deviation a is calculated based on the volume-based particle diameter of the microcapsule measured according to the above measurement method of the median diameter.

—Thickness of Wall—

The thickness (wall thickness) of the capsule wall of the microcapsule is not particularly limited, but as the wall is thinner, the deformation easily occurs, the void is easily reduced and/or the contact area between the microcapsules is easily widened, so that the occurrence of defects when handling it can be further suppressed. Specifically, it is preferably 10 μm or less, more preferably less than 0.2 μm, further preferably 0.15 μm or less, and particularly preferably 0.11 μm or less. On the other hand, the strength of the capsule wall can be maintained by having a certain thickness, and thus the wall thickness is preferably 0.01 μm or more, and more preferably 0.05 μm or more.

The wall thickness refers to an average value obtained by calculating and averaging the individual wall thicknesses (μm) of any 20 microcapsules by using a scanning electron microscope (SEM).

Specifically, a cross-sectional slice of the heat storage sheet is manufactured, the cross section is observed by using the SEM, 20 microcapsules are selected from the microcapsules which have a size of ±10% of the median diameter calculated by the measurement method described above. The cross sections of the individual microcapsules which are selected are observed, the wall thicknesses are measured, and the average value of 20 microcapsules is calculated to obtain the wall thickness of the microcapsule.

In a case in which the volume-based median diameter of the microcapsule described above is Dm [unit: μm] and the thickness of the capsule wall of the microcapsule described above is δ [unit: μm], a ratio (6/Dm) of the thickness of the capsule wall of the microcapsule to the volume-based median diameter of the microcapsule is preferably 0.02 or less, more preferably 0.0075 or less, further preferably 0.006 or less, and particularly preferably 0.005 or less. In a case in which 6/Dm is 0.0075 or less, the microcapsule in a case of manufacturing the heat storage sheet can be easily deformed, so that the void volume of the heat storage sheet can be particularly reduced and/or the adjacency ratio of the microcapsule which will be described below can be particularly increased.

From the viewpoint of being capable of maintaining the strength of the microcapsule, the lower limit value of 6/Dm is preferably 0.001 or more, more preferably 0.0015 or more, and further preferably 0.0025 or more.

—Deformation Rate—

The deformation rate of the microcapsule is not particularly limited, but a larger deformation rate is preferable from the viewpoints of being capable of reducing the void volume of the capsule and being capable of increasing the capsule adjacency ratio. Where, the deformation rate of the microcapsule refers to a value measured by the following method.

By directly extracting from the coating liquid before forming into a sheet or by eluting from the heat storage sheet with the solvent, 15 microcapsules which have a particle diameter within ±10% of the average value are extracted. The microcapsules are heated on a hot plate set to 5 degree above temperature at which the encapsulating component melts, to cause the encapsulating component to melt. For the microcapsules in which the encapsulating component melts, by using an indentation type hardness meter, a 0.1 mm square flat indenter thereof is brought into contact with the hardness meter, and then pressed with a maximum indentation load of 1 mN to measure the maximum value (maximum indentation depth) of the distance that the flat indenter sinks.

From the above measurement result, the value of (maximum indentation depth (unit: μm))/(median diameter Dm of the microcapsule (unit: μm))×100 is calculated, and the average value obtained by averaging the measured 15 capsules is defined as the deformation rate of the microcapsule. The larger deformation rate means that the microcapsule is largely deformed. As the indentation type hardness meter, an HM2000 type micro hardness meter manufactured by FISCHER INSTRUMENTS K. K. can be used.

The deformation rate of the microcapsule is preferably 30% or more, more preferably 35% or more, further preferably 40% or more, and particularly preferably 50% or more. As the value of the deformation rate is larger, the adhesion of the heat storage member can be improved. In particular, in a case in which the deformation rate is 35% or more, the adhesion of the heat storage member is more excellent, which is preferable. The upper limit thereof is not particularly limited, but it is, for example, 100% or less, preferably 60% or less, from the viewpoint of ease of handling in a case of manufacturing, and the like.

The deformation rate of the microcapsule can be adjusted depending on, for example, the thickness of the capsule wall of the microcapsule, the ratio (6/Dm) of the thickness of the capsule wall of the microcapsule to the volume-based median diameter of the microcapsule, and the material which forms the capsule wall.

The content of the microcapsule in the heat storage sheet is not particularly limited, but from the viewpoint of more excellent heat storage property of the heat storage member, it is preferably 75% by mass or more, more preferably 80% by mass or more, further preferably 85% to 99% by mass, and particularly preferably 90% to 99% by mass, based on the total mass of the heat storage sheet.

(Manufacturing Method of Microcapsule)

The manufacturing method of the microcapsule is not particularly limited, and a known method can be adopted.

For example, in a case in which the capsule wall includes polyurethane urea, polyurethane, or polyurea, there is an interfacial polymerization method including a step (emulsification step) of dispersing the oil phase including the heat storage material and a capsule wall material in the water phase including the emulsifier to prepare an emulsified liquid, and a step (capsulizing step) of polymerizing the capsule wall material at the interface between the oil phase and the water phase to form the capsule wall, and forming the microcapsule which encapsulates the heat storage material.

In a case in which the capsule wall includes a melamine resin, a coacervation method including a step (emulsification step) of dispersing the oil phase including the heat storage material in the water phase including the emulsifier to prepare the emulsified liquid, and a step (capsulizing step) of adding the capsule wall material to the water phase, forming a polymer layer of the capsule wall material on a surface of emulsified liquid droplet, and forming the microcapsule which encapsulates the heat storage material can be used, for example.

The capsule wall material refers to a material which can form the capsule wall.

Each step of the interfacial polymerization method will be described in detail in the following.

In the emulsification step of the interfacial polymerization method, the emulsified liquid is prepared by dispersing the oil phase including the heat storage material and the capsule wall material in the water phase including the emulsifier. The capsule wall material includes at least polyisocyanate and at least one compound selected from the group consisting of polyol and polyamine.

The emulsified liquid is formed by dispersing the oil phase including the heat storage material and the capsule wall material in the water phase including the emulsifier.

The oil phase includes at least the heat storage material and the capsule wall material, and as needed, may further include other components such as the solvent, and/or the additive. As the solvent which may be included in the oil phase, from the viewpoint of excellent dispersion stability, a water-insoluble organic solvent is preferable, and ethyl acetate, methyl ethyl ketone, or toluene is more preferable.

The water phase can include at least an aqueous medium and the emulsifier.

As an example of the aqueous medium, there are water, and a mixed solvent of water and a water-soluble organic solvent, and it is preferably water. The “water-soluble” means that a dissolved amount of a target substance in 100% by mass of water at 25° C. is 5% by mass or more.

The content of the aqueous medium is not particularly limited, but it is preferably 20% to 80% by mass, more preferably 30% to 70% by mass, and further preferably 40% to 60% by mass, based on the total mass of the emulsified liquid which is a mixture of the oil phase and the water phase.

Examples of the emulsifier include a dispersing agent, a surfactant, or a combination thereof.

Examples of the dispersing agent include a binder which will be described below, and it is preferably polyvinyl alcohol.

Examples of the surfactant include a nonionic surfactant, an anionic surfactant, a cationic surfactant, and an amphoteric surfactant. The surfactant may be used alone, or may be used in the combination of two types or more.

The content of the emulsifier is preferably more than 0% by mass and 20% by mass or less, more preferably 0.005% to 10% by mass, further preferably 0.01% to 10% by mass, and particularly preferably 1% to 5% by mass, based on the total mass of the emulsified liquid which is a mixture of the oil phase and the water phase.

The water phase may include other components such as an ultraviolet absorbing agent, an antioxidant, and a preservative, as needed.

Dispersion refers to dispersing the oil phase as oil droplets in the water phase (emulsification). Dispersion can be performed by using a unit usually used to disperse the oil phase and the water phase (for example, homogenizer, manton gaulin, ultrasound disperser, dissolver, keddy mill, and other known dispersion apparatuses).

The mixing ratio of the oil phase to the water phase (oil phase mass/water phase mass) is preferably 0.1 to 1.5, more preferably 0.2 to 1.2, and further preferably 0.4 to 1.0.

—Capsulizing Step—

In the capsulizing step, the capsule wall material is polymerized at the interface between the oil phase and the water phase to form the capsule wall, and microcapsule which encapsulates the heat storage material is formed.

The polymerization is preferably performed under heating. A reaction temperature in the polymerization is preferably 40° C. to 100° C., and more preferably 50° C. to 80° C. A reaction time of polymerization is preferably about 0.5 to 10 hours, and more preferably about 1 to 5 hours.

In order to prevent the aggregation of the microcapsules during polymerization, it is preferable that an aqueous solution (for example, water, an aqueous acetic acid solution, or the like) be further added to reduce the collision probability between the microcapsules.

Also, it is preferable that sufficient stirring be performed.

Further, a dispersing agent for preventing aggregation may be added to a reaction system during the polymerization.

Further, as needed, a charge adjusting agent such as nigrosin or any other auxiliary agent may be added to the reaction system during the polymerization.

<Binder>

It is preferable that the heat storage sheet include the binder in addition to the microcapsule. The heat storage sheet includes the binder, so that the durability of the heat storage sheet is improved.

The binder is not particularly limited as long as it is a polymer which can form a film, and examples thereof include a water-soluble polymer, and an oil-soluble polymer.

The “water-soluble” in the water-soluble polymer means that the dissolved amount of the target substance in 100% by mass of water at 25° C. is 5% by mass or more, and a more suitable water-soluble polymer has a dissolved amount of 10% by mass or more.

The “oil-soluble” of the oil-soluble polymer means that a dissolved amount of a target substance in 100% by mass of water at 25° C. is less than 5% by mass.

Examples of the water-soluble polymer include polyvinyl alcohol (unmodified polyvinyl alcohol and modified polyvinyl alcohol), polyacrylic acid amide and its derivative, an ethylene-vinyl acetate copolymer, a styrene-maleic acid anhydride copolymer, an ethylene-maleic acid anhydride copolymer, an isobutylene-maleic acid anhydride copolymer, polyvinylpyrrolidone, an ethylene-acrylic acid copolymer, a vinyl acetate-acrylic acid copolymer, carboxymethyl cellulose, methyl cellulose, casein, gelatin, a starch derivative, gum arabic, and sodium alginate.

Examples of the oil-soluble polymer include polymers having the heat storage property disclosed in WO2018/207387A, and JP2007-031610A.

Among these, as the binder, a water-soluble polymer is preferable, polyol is more preferable, polyvinyl alcohol is further preferable, and modified polyvinyl alcohol is particularly preferable. To use the water-soluble polymer is suitable for forming the heat storage sheet while maintaining the dispersibility in a case in which an oil in a water type (0/W type) microcapsule liquid in which the core material is the oil-soluble material such as paraffin is prepared. Further, in a case in which the modified polyvinyl alcohol is used, the void volume of the heat storage sheet can be preferably reduced and/or the adjacency ratio of the microcapsule which will be described below can be preferably increased.

Of the polyvinyl alcohol, unmodified polyvinyl alcohol is obtained, for example, by substituting at least a part of an acetic acid group of polyvinyl acetate with a hydroxyl group by a saponification reaction. The polyvinyl alcohol may be polyvinyl alcohol in which only a part of an acetic acid group of polyvinyl acetate is substituted with a hydroxyl group (partially saponified polyvinyl alcohol), or may be polyvinyl alcohol in which all of an acetic acid group of polyvinyl acetate is substituted with a hydroxyl group (fully saponified polyvinyl alcohol).

The modified polyvinyl alcohol means polyvinyl alcohol which has a modified group. From the viewpoints of being capable of further reducing the void volume of the heat storage sheet and/or being capable of further increasing the adjacency ratio of the microcapsule which is described below, the modified group is preferably at least one group selected from the group consisting of a carboxy group or a salt thereof and an acetoacetyl group.

As the salt of the carboxy group, a metal salt of the carboxy group is preferable and a sodium salt of the carboxy group is more preferable.

The modified polyvinyl alcohol can be obtained, for example, by saponifying a polymer obtained by copolymerizing a monomer which has a modified group and vinyl ester (for example, vinyl acetate, or the like). Further, the modified polyvinyl alcohol may be obtained by causing a hydroxyl group or an acetic acid group in the unmodified polyvinyl alcohol to react with a compound which has a modified group.

Examples of the polyvinyl alcohol include Kuraray Poval series manufactured by Kuraray Co., Ltd. (for example, Kuraray Poval PVA-217E, Kuraray Poval KL-318, or the like), GOHSENX series manufactured by Mitsubishi Chemical Corporation (for example, GOHSENX Z-320, or the like), A series manufactured by Japan Vam & Poval Co., Ltd. (for example, AP-17, or the like).

The degree of polymerization of polyvinyl alcohol is preferably 500 to 5000, more preferably 1000 to 3000, and further preferably 2000 to 3000.

A number average molecular weight (Mn) of the binder is not particularly limited, but from the viewpoint of the film hardness, it is preferably 20,000 to 300,000, and more preferably 20,000 to 150,000.

For the measurement of molecular weight, a value is measured by gel permeation chromatography (GPC).

For the measurement by gel permeation chromatography (GPC), HLC (registered trademark)-8020 GPC (manufactured by Tosoh Corporation) is used as a measuring device, and three TSK gel (registered trademark) Super Multipore HZ-H (4.6 mm ID×15 cm, manufactured by Tosoh Corporation) are used as a column, and THF (tetrahydrofuran) is used as the eluent. As a measurement condition, a sample concentration is 0.45% by mass, a flow rate is 0.35 ml/min, a sample injection amount is 10 μl, a measurement temperature is 40° C., and a refractive index (RI) detector is used.

A calibration curve is produced from 8 samples of “standard sample TSK standard polystyrene” manufactured by Tosoh Corporation: “F-40”, “F-20”, “F-4”, “F-1”, “A-5000”, “A-2500”, “A-1000”, and “n-propylbenzene”.

The content of the binder in the heat storage sheet is not particularly limited, but from the viewpoints of the balance between the film hardness of the heat storage sheet and the heat storage property of the heat storage member, it is preferably 0.1% to 20% by mass, and more preferably 1% to 11% by mass.

In a case in which the binder includes a water-soluble polymer, from the viewpoints of being capable of increasing the content ratio of the heat storage material to the total mass of the heat storage sheet and being capable of further improving the heat storage property of the heat storage sheet, the content of the water-soluble polymer to the total mass of the binder is preferably 85% by mass or more, more preferably 90% by mass or more, and further preferably 95% by mass or more. It is preferable that the upper limit be 100% by mass.

<Water>

The heat storage sheet may contain water, but in a case in which the water contained in the heat storage sheet evaporates, a portion in which the water evaporates may become a void in the heat storage sheet. Therefore, the content of water in the heat storage sheet is preferably small, from the viewpoint of suppressing the generation of void. Specifically, from the viewpoint of further suppressing the generation of void in the heat storage sheet, the content of water in the heat storage sheet to the total mass of the heat storage sheet is preferably 5% by mass or less, more preferably 2% by mass or less, and further preferably 1% by mass or less.

The lower limit of the content of water in the heat storage sheet is not particularly limited, but 0% by mass can be adopted, for example.

The measurement method of the content of water in the heat storage sheet is as follows. First, the heat storage sheet is stored for 24 hours in a constant-temperature and constant-humidity tank at 25% RH and 40° C. to obtain a heat storage sheet A. The heat storage sheet A extracted from the constant-temperature and constant-humidity tank is dried at 100° C. for 3 hours to obtain a heat storage sheet B. The masses of the heat storage sheet A and the heat storage sheet B which are obtained as above are measured, and the value obtained according to the following equation is defined as the content of water in the heat storage sheet.

Content of water in heat storage sheet (% by mass)=100×{(mass of heat storage sheet A)−(mass of heat storage sheet B)}/(mass of heat storage sheet A)

<Other Components>

The heat storage sheet may include components other than the microcapsule and the binder. Examples of other components include a thermal conductive material, a flame retardant, an ultraviolet absorbing agent, an antioxidant, and a preservative.

The content of other components is preferably 10% by mass or less, and more preferably 5% by mass or less, based on the total mass of the heat storage sheet. The lower limit is not particularly limited, but 0% by mass can be adopted, for example.

For the “thermal conductivity” of the thermal conductive material, a material having the thermal conductivity of 10 Wm⁻¹ K⁻¹ or more is preferable. Above all, the thermal conductivity of the thermal conductive material is more preferably 50 Wm⁻¹K⁻¹ or more, from the viewpoint of improving the heat radiation property of the heat storage sheet.

The thermal conductivity (unit: Wm⁻¹K⁻¹) is a value measured by a flash method at a temperature of 25° C. by a method compliant with Japanese Industrial Standards (JIS) R1611.

<Physical Property of Heat Storage Sheet>

(Thickness)

The thickness of the heat storage sheet is not particularly limited, but it is preferably 1 to 1000 μm.

The thickness is an average value obtained by observing the cut cross section of the heat storage sheet cut in parallel to the thickness direction with SEM, measuring any 5 points, and averaging the thicknesses of the 5 points.

(Latent Heat Capacity)

The latent heat capacity of the heat storage sheet is not particularly limited, but from the viewpoints of the high heat storage property of the heat storage member and the suitability for temperature control of a heat generating body which generates heat, it is preferably 115 J/ml or more, more preferably 120 J/ml or more, and further preferably 130 J/ml or more. The upper limit is not particularly limited, but it is preferably 300 J/ml or less.

The latent heat capacity is a value calculated from the result of the differential scanning calorimetry (DSC) and the thickness of the heat storage sheet.

In a case in which it is considered that a high amount of heat storage in a limited space is exhibited, it is considered appropriate to grasp the amount of heat storage in terms of “J/ml (amount of heat storage per unit volume)”, but in a case in which the applications to the electronic device are considered, the weight of the electronic device is also important. Therefore, in a case in which it is considered that a high heat storage property is exhibited in a limited mass, it may be appropriate to grasp the heat storage property in terms of “J/g (amount of heat storage per unit mass)”. In this case, the latent heat capacity is preferably 150 J/g or more, and more preferably 160 J/g or more. The upper limit is not particularly limited, but it is preferably 300 J/g or less.

(Volume Fraction of Microcapsule)

A volume fraction of the microcapsule in the heat storage sheet is not particularly limited, but it is preferably 60% by volume or more, more preferably 80% by volume or more, and further preferably 90% by volume or more, based on the total volume of the heat storage sheet. The upper limit is not particularly limited, but 100% by volume or less can be adopted, for example.

(Void Volume)

The void volume of the heat storage sheet means the volume fraction of the void in the heat storage sheet. Where, the void refers to a region in which the material (solid and liquid) which configures the heat storage sheet is not present and is surrounded by the material which configures the heat storage sheet in the heat storage sheet, and is usually filled with gas (mainly, air).

The void volume of the heat storage sheet is less than 10% by volume based on the total volume of the heat storage sheet, and is preferably 5% by volume or less, more preferably 4% by volume or less, further preferably 3% by volume or less, and particularly preferably 2% by volume or less, from the viewpoint of being capable of further suppressing the occurrence of defects in the heat storage sheet when handling it. The lower limit of the void volume of the heat storage sheet is not particularly limited, but 0% by volume can be adopted, for example.

Further, in a case in which the void volume of the heat storage sheet is less than 10% by volume, the amount of heat storage per unit volume can be further improved.

Further, in a case in which the void volume of the heat storage sheet is less than 10% by volume, the contact area between the microcapsules becomes wide, so that the modulus of elasticity of the heat storage sheet tends to be increased. As a result, in a case in which the heat storage sheet adheres to other members via the adhesion layer which will be described below, the stiffness of the heat storage sheet is increased by the microcapsule. As a result, of the force (pressure sensitive adhesive strength) in a case in which the heat storage sheet is peeled off from other members, the force required to bend the heat storage sheet is increased, so the adhesiveness between the heat storage sheet and other members (force required to peel off the heat storage sheet from other members) is improved.

Examples of the method of setting the void volume of the heat storage sheet to less than 10% by volume include a method of lengthening the drying time during the manufacturing of the heat storage sheet, a method of increasing the drying temperature during the manufacturing of the heat storage sheet, a method of using the microcapsule having thin wall thickness, a method using the microcapsule having small value of 6/Dm, and a method in which two or more of these method are combined.

The void volume of the heat storage sheet is calculated based on image data obtained by a known X-ray computed tomography (CT) apparatus based on the X-ray CT method as a measurement principle.

Specifically, any region of 1 mm×1 mm in the in-plane direction of the heat storage sheet is scanned along the film thickness direction of the heat storage sheet by the X-ray CT method, and gas (air) and the others (solid and liquid) are distinguished. Then, from the three-dimensional image data obtained by performing image processing on a plurality of scanning layers obtained by scanning along the film thickness direction, the volume of the gas (void portion) which is present in the scanned region and total volume of the scanned region (total volume of gas, solid, and liquid) are obtained. Then, the ratio of the volume of the gas to the total volume of the scanned region is defined as the void volume (% by volume) of the heat storage sheet.

(Adjacency Ratio of Microcapsule)

The adjacency ratio of microcapsule is an index which shows the degree of adjacency (contact) between microcapsules included in the heat storage sheet, and is obtained from the image obtained by observing the cross section of the heat storage sheet using SEM (hereinafter, also referred to as “SEM cross sectional image”) by using the following equation.

Adjacency ratio (%)=total length of adjacent portion of microcapsule (μm)/length of outer circumference of microcapsule (μm)×100

In the present specification, “the microcapsules are adjacent to each other” means that the distance between the capsule walls of the two microcapsules is 5% or less based on the median diameter calculated by the measurement method described above. Further, the “adjacent portion” in the above equation means a section of the outer circumference of the microcapsule in which the distance from the other microcapsule (distance between walls) is 5% or less of the capsule diameter.

Specifically, the adjacency ratio of microcapsule is obtained by the following method. A slice is manufactured by cutting the heat storage sheet along the normal direction of the main surface of the heat storage sheet (or heat storage member) such that the shape and the disposition of the microcapsules in the heat storage sheet are maintained to obtain the SEM cross sectional image. The method of manufacturing the slice of the heat storage sheet in this case is not particularly limited, and examples thereof include a method of manufacturing a very thin slice of the heat storage sheet using a microtome and observing the obtained slice by SEM. From the obtained image, 20 microcapsules which have a size of ±10% of the median diameter calculated by the measurement method described above are selected, and the outer circumference lengths of the selected microcapsules are measured. Further, in the selected microcapsules, the length of the adjacent portion of the outer circumference in which the distance from the other microcapsules is 5% or less of the median diameter is measured. From the total length (μm) of the outer circumference of the obtained microcapsules and the total length of the adjacent portions (μm), the adjacency ratio is calculated by using the above equation, and the average value of the adjacency ratios of 20 microcapsules is obtained.

The adjacency ratio of the microcapsule in the heat storage sheet is preferably 80% or more, more preferably 85% or more, further preferably 90% or more, and particularly preferably 96% or more, from the viewpoint of suppressing the occurrence of defects when handling it. The upper limit is not particularly limited, but it may be, for example, 99.9% or less.

Further, in a case in which the volume ratio of the microcapsule is within the above range, the amount of heat storage per unit volume can be further improved.

Further, in a case in which the volume ratio of the microcapsule is within the above range, the contact area between the microcapsules becomes wide, so that the modulus of elasticity of the heat storage sheet tends to be increased. As a result, the adhesiveness between the heat storage sheet and other members is improved as in the case in which the void volume of the heat storage sheet is low.

Examples of the method of setting the volume ratio of the microcapsule within the above range include the method described as a method of reducing the void volume of the heat storage sheet.

(Aspect Ratio of Microcapsule)

As described above, it is preferable that the microcapsules included in the heat storage sheet be deformed. Above all, the aspect ratio of the microcapsule is preferably 1.2 or more, more preferably 1.5 or more, and further preferably 2.0 or more.

In a case in which the aspect ratio of the microcapsule is within the above range, the filling rate of the microcapsule is improved, so that the contact area between the microcapsules is widened, the strength of the heat storage sheet is improved, and the occurrence of defects in the heat storage sheet when handling it can be further suppressed. Further, by improving the filling rate of the microcapsule, the amount of the heat storage material is increased, and more excellent heat storage property can be realized.

The upper limit of the aspect ratio of the microcapsule is not particularly limited, but it may be, for example, 10% or less.

The aspect ratio of the microcapsule can be obtained from the SEM cross sectional image of the heat storage sheet by the following method. In the same manner as the method of calculating the adjacency ratio described above, after the SEM cross sectional image is obtained, 20 microcapsules are selected from the obtained image. Of the two parallel tangents which are circumscribed on the outer circumference of each selected microcapsule, the distance between the two parallel tangents selected such that the distance between the tangents is maximized is defined as a length L of the long side. Further, of the two parallel tangents orthogonal to the two parallel tangents which provide the length L and which are circumscribed on the outer circumference of the microcapsule, the distance between the tangents selected such that the distance between the tangents is maximized is defined as a length S of the short side. From the length L (μm) of the long side and the length S (μm) of the short side which are obtained, the aspect ratio is calculated by using the following equation, and the average value of 20 microcapsules is obtained.

Aspect ratio=L (μm)/S (μm)

Examples of the method of setting the aspect ratio of the microcapsule within the above range include the method described as a method of reducing the void volume of the heat storage sheet.

(Shape of Microcapsule)

Further, it is preferable that the microcapsule included in the heat storage sheet have a flat portion or a recess portion formed by contact with other microcapsules or the like.

Specifically, it is preferable that the microcapsule in the heat storage sheet observed by the following method have two or more flat portions and recess portions. By the same method as the method of calculating the adjacency ratio described above, after the SEM cross sectional image is obtained, 20 microcapsules are selected. Next, confirm is made as on whether or not the condition that the microcapsules selected from the SEM cross sectional image form a portion in which at least two or more microcapsules are adjacent to each other, and in the outer shape of the selected microcapsules, two or more linear portions or recess portions formed along the outer shape of the microcapsules adjacent each other are included is satisfied. Among the 20 selected microcapsules, the number of microcapsules which satisfy the above conditions is preferably 5 or more, more preferably 10 or more, and further preferably 20.

(Modulus of Elasticity)

The modulus of elasticity (modulus of tensile elasticity) of the heat storage sheet is not particularly limited, but it is preferably 1700 MPa or more, more preferably 2000 MPa or more, further preferably 3700 MPa or more, and particularly preferably 4000 MPa or more.

The upper limit of the modulus of elasticity of the heat storage sheet is not particularly limited, but it is preferably 10000 MPa or less.

The modulus of elasticity (modulus of tensile elasticity) of the heat storage sheet is measured according to JIS K7161-1: 2014.

### Heat Storage Sheet (Second Embodiment)

A heat storage sheet according to a second embodiment of the present invention includes a microcapsule which encapsulates a heat storage material, in which an adjacency ratio of the microcapsule is 80% by volume or more.

With the heat storage sheet according to the second embodiment, the occurrence of defects when handling it can be suppressed. In a case in which the adjacency ratio of the heat storage sheet is high, it is considered that a contact area between the microcapsules in the heat storage sheet becomes large, so that the strength of the heat storage sheet is improved. As a result, it is presumed that the brittleness of the heat storage sheet is increased and the occurrence of defects (for example, cracks and breaks) when handling it of the heat storage sheet can be suppressed.

The composition (core material (heat storage material), material which forms the capsule wall, and the like), physical property (particle diameter, thickness of the capsule wall, and the like), the content, and a manufacturing method of the microcapsule included in the heat storage sheet according to the present embodiment are the same as those of the microcapsule included in the heat storage sheet according to the first embodiment described above, which includes the suitable embodiment thereof.

Further, the binder included in the heat storage sheet according to the present embodiment and the components other than the microcapsule such as water are the same as those of the heat storage sheet according to the first embodiment described above, which includes the suitable embodiment thereof.

The adjacency ratio of the microcapsule included in the heat storage sheet according to the present embodiment is 80% or more, from the viewpoint of being capable of further suppressing the occurrence of defects when handling it, is preferably 85% or more, more preferably 90% or more, and further preferably 96% or more. The upper limit is not particularly limited, but it may be, for example, 99.9% or less.

Further, in a case in which the adjacency ratio of the microcapsule is 80% or more, the amount of heat storage per unit volume can be further improved.

Further, in a case in which the adjacency ratio of the microcapsule is 80% or more, the contact area between the microcapsules becomes wide, so that the modulus of elasticity of the heat storage sheet tends to be increased. As a result, in a case in which the heat storage sheet adheres to other members via the adhesion layer which will be described below, the stiffness of the heat storage sheet is increased by the microcapsule. As a result, of the force (pressure sensitive adhesive strength) in a case in which the heat storage sheet is peeled off from other members, the force required to bend the heat storage sheet is increased, so the adhesiveness between the heat storage sheet and other members (force required to peel off the heat storage sheet from other members) is improved.

The measurement method of the adjacency ratio of the microcapsule and the method of adjusting the adjacency ratio of the microcapsule have already been described for the heat storage sheet according to the first embodiment.

From the viewpoint of being capable of further suppressing the occurrence of defects in the heat storage sheet when handling it, the void volume of the heat storage sheet according to the present embodiment is preferably less than 10% by volume, more preferably 5% by volume or less, further preferably 4% by volume or less, particularly preferably 3% by volume or less, and most preferably 2% by volume or less, based on the total volume of the heat storage sheet. The lower limit of the void volume of the heat storage sheet is not particularly limited, but 0% by volume can be adopted, for example.

Further, in a case in which the void volume of the heat storage sheet is within the above range, the amount of heat storage per unit volume can be further improved.

Further, in a case in which the void volume of the heat storage sheet is within the above range, the contact area between the microcapsules becomes wide, so that the modulus of elasticity of the heat storage sheet tends to be increased. As a result, in a case in which the heat storage sheet adheres to other members via the adhesion layer which will be described below, the stiffness of the heat storage sheet is increased by the microcapsule. As a result, of the force (pressure sensitive adhesive strength) in a case in which the heat storage sheet is peeled off from other members, the force required to bend the heat storage sheet is increased, so the adhesiveness between the heat storage sheet and other members (force required to peel off the heat storage sheet from other members) is improved.

The measurement method of the void volume of the microcapsule and the method of adjusting the void volume of the microcapsule have already been described for the heat storage sheet according to the first embodiment.

Among the physical properties of the heat storage sheet according to the present embodiment, the thickness, the latent heat capacity, the volume fraction of the microcapsule, the aspect ratio of the microcapsule, the shape of the microcapsule, and the modulus of elasticity are the same as those of the heat storage sheet according to the first embodiment described above, which includes the suitable embodiment thereof.

[Manufacturing Method of Heat Storage Sheet]

The manufacturing method of the heat storage sheet (including the heat storage sheet according to the first embodiment or the heat storage sheet according to the second embodiment, and the same applies to the following) is not particularly limited, and known methods can be adopted. For example, there is a manufacturing method of applying the dispersion liquid which includes the microcapsule and the binder or the like used as needed onto the base material and drying the liquid.

As needed, a simple substance of the heat storage sheet can be obtained by peeling off the base material from the laminate of the obtained base material and the heat storage sheet.

As an example of the base material, there are a resin base material, a glass base material, and a metal base material. Examples of the resin included in the resin base material include polyester (for example, polyethylene terephthalate and polyethylene naphthalate), polyolefin (for example, polyethylene and polypropylene), and polyurethane. It is preferable to add a function of improving the thermal conductivity in a plane direction or a film thickness direction and to quickly diffusing heat from a heat generating portion to a heat storage portion to the base material. The base material formed by combining the metal base material with the thermal conductive material such as a graphite sheet or a graphene sheet is more preferable.

The thickness of the base material is not particularly limited, but it is preferably 1 to 100 μm, more preferably 1 to 25 μm, and further preferably 3 to 15 μm.

It is preferable that a surface of the base material be subjected to surface treatment of the base material for a purpose of improving the adhesiveness to the heat storage sheet. Examples of a surface treatment method include corona treatment, plasma treatment, providing of a thin layer which is an easily adhesive layer, and the like.

The material which configures the easily adhesive layer is not particularly limited, but examples thereof include a resin, more specifically, there are styrene-butadiene rubber, an urethane resin, an acrylic resin, a silicone resin, and a polyvinyl resin.

The thickness of the easily adhesive layer is not particularly limited, but it is preferably 0.1 to 5 μm, and more preferably 0.5 to 2 μm.

As the base material, a temporary base material which is able to be peeled off may be used.

As the coating method, for example, there are a die coating method, an air knife coating method, a roll coating method, a blade coating method, a gravure coating method, and a curtain coating method.

The drying temperature has a preferable range depending on the amount of water in a case of drying, but in a case of water, from the viewpoints of being capable of reducing the void volume of the heat storage sheet and/or being capable of increasing the adjacency ratio of the microcapsule, it is preferably 20° C. to 130° C., more preferably 30° C. to 120° C., and further preferably 33° C. to 100° C.

The drying time is preferably terminated immediately before the moisture in the film is completely dried, but within that range, it is preferably 30 seconds or longer, and more preferably 1 minute or longer, from the viewpoints of being capable of reducing the void volume of the heat storage sheet and/or being capable of increasing the adjacency ratio of the microcapsule. From the viewpoint of the manufacturing efficiency of the heat storage sheet, the lower upper limit of the drying time is better.

The coating film may be subjected to the flattening treatment in the step of drying. Examples of the flattening treatment method include a method of applying pressure to the coating film by using a roller, a nip roller, a calender, or the like to increase the filling rate of microcapsule in the film.

Further, in order to reduce the void volume in the heat storage sheet and/or further improve the adjacency ratio of the microcapsule, the method, such as using the microcapsule which is easily deformed (deformation rate is large), performing drying gently in a case in which the coating film is formed, or performing coating in a plurality of times without forming a thick coating film at one time, is preferable.

[Application of Heat Storage Sheet]

The heat storage sheet according to the embodiment of the present invention can be applied to various applications, for example, it can be used in applications such as an electronic device (for example, mobile phones (in particular, smartphones), personal digital assistants, personal computers (in particular, portable personal computers), game machines, remote controls, or the like); building materials which are suitable for temperature control to rapid temperature rise during the day or during indoor heating and cooling (for example, flooring materials, roofing materials, wall materials, and the like); clothing which is suitable for temperature control depending on the changes in environmental temperature or changes in body temperature during exercise or rest (for example, underwear, outerwear, winter clothes, gloves, and the like); bedding; and an exhaust heat utilization system which stores unnecessary exhaust heat and uses it as heat energy.

Among these, it is preferable to apply the heat storage sheet to the electronic device (in particular, a portable electronic device). The reason is as follows.

As a method of suppressing the temperature rise due to heat generation of the electronic device, a method of discharging heat to the outside of the electronic device by an air flow, and a method of diffusing heat to the entire housing of the electronic device by a heat pipe, a heat spreader, or the like are used. However, from the viewpoint of thinning and waterproofness of the electronic device in recent years, the airtightness of the electronic device is improved, and it is difficult to adopt the method of discharging heat by the air flow, and thus among the above methods, the method of diffusing heat to the entire housing of the electronic device is used. Therefore, suppressing of the temperature rise of the electronic device is limited.

To solve this problem, by introducing the heat storage sheet described above into the electronic device, it is possible to suppress the temperature rise of the electronic device while maintaining the airtightness and waterproofness of the electronic device. That is, since the heat storage sheet creates a portion in the electronic device in which heat can be stored for a certain period of time, the surface temperature of the heat generating body in the electronic device can be maintained in any temperature range.

[Heat Storage Member]

The heat storage member according to the embodiment of the present invention includes the heat storage sheet described above (including the heat storage sheet according to the first embodiment or the heat storage sheet according to the second embodiment). The heat storage member may be a roll type. Further, it may be produced by cutting out or punching out the heat storage member in the roll type or a sheet type into a desired size and shape.

It is preferable that the heat storage member further include the protective layer. Further, it is preferable that the heat storage member have the base material on the heat storage sheet, from the viewpoint of handling.

<Protective Layer>

The protective layer is a layer disposed on the heat storage sheet, and in a case in which the heat storage member includes the base material, the protective layer is disposed on the surface side of the heat storage sheet opposite to the base material. The protective layer has a function of heat storage sheet protection.

The protective layer may be disposed so as to be in contact with the heat storage sheet, or may be disposed on the heat storage sheet via another layer.

The material which configures the protective layer is not particularly limited, and resin is preferable, and resin selected from the group consisting of a fluororesin and a siloxane resin is preferable from the viewpoint of further improving water resistance and flame retardance.

Examples of the fluororesin include a known fluororesin. As an example of the fluororesin, there are polytetrafluoroethylene, polyvinyl fluoride, polyvinylidene fluoride, polychlorotrifluoroethylene, and polytetrafluoropropylene.

The fluororesin may be a homopolymer obtained by polymerizing a single monomer, or may be a polymer obtained by copolymerizing two or more types. Further, a copolymer of these monomers and other monomers may be used.

As an example of the copolymer, there are a copolymer of tetrafluoroethylene and tetrafluoropropylene, a copolymer of tetrafluoroethylene and vinylidene fluoride, a copolymer of tetrafluoroethylene and ethylene, a copolymer of tetrafluoroethylene and propylene, a copolymer of tetrafluoroethylene and vinyl ether, a copolymer of tetrafluoroethylene and perfluorovinyl ether, a copolymer of chlorotrifluoroethylene and vinyl ether, and a copolymer of chlorotrifluoroethylene and perfluorovinyl ether.

Examples of the fluororesin include Obbligato (registered trademark) SW0011F manufactured by AGC COAT-TECH Co., Ltd., SIFCLEAR-F101 and F102 (manufactured by JSR corporation), KYNAR AQUATEC (registered trademark) ARC and FMA-12 (both manufactured by Arkema).

The siloxane resin is a polymer which has a repeating unit having a siloxane skeleton, and a hydrolysis condensate of a compound represented by Formula (1) as follows is preferable.

Si(X)ₙ(R)₄₋ₙ Formula (1)

X indicates a hydrolyzable group. As an example of the hydrolyzable group, there are an alkoxy group, a halogen group, an acetoxy group, and an isocyanate group.

R indicates a non-hydrolyzable group. Examples of the non-hydrolyzable group include an alkyl group (for example, a methyl group, an ethyl group, and a propyl group), an aryl group (for example, a phenyl group, a tolyl group, and a mesityl group), an alkenyl group (for example, a vinyl group and an allyl group), haloalkyl group (for example, a γ-chloropropyl group), an aminoalkyl group (for example, a γ-aminopropyl group and γ-(2-aminoethyl) aminopropyl group), an epoxy alkyl group (for example, a γ-glycidoxypropyl group and a β-(3,4-epoxycyclohexyl) ethyl group), a γ-mercapto alkyl group, a (meth)acryloyloxyalkyl group (a γ-methacryloyloxypropyl group), and a hydroxyalkyl group (for example, a γ-hydroxypropyl group).

n indicates an integer of 1 to 4, and is preferably 3 or 4.

The above hydrolysis condensate is intended to be a compound obtained by hydrolyzing the hydrolyzable group in the compound represented by Formula (1) and condensing the obtained hydrolyzate. The hydrolysis condensate may be a condensate in which all of the hydrolyzable groups are hydrolyzed, and all of the hydrolyzates are condensed (full hydrolysis condensate), or may be a condensate in which a part of the hydrolyzable group is hydrolyzed, and a part of the hydrolyzate is condensed (partial hydrolysis condensate). That is, the hydrolysis condensate may be a full hydrolysis condensate, a partial hydrolysis condensate, or a mixture thereof.

For example, as the protective layer, a layer which includes a known hard coating agent or a hard coating film as disclosed in JP2018-202696A, JP2018-183877A, and JP2018-111793A may be used. From the viewpoint of the heat storage property, the protective layer which includes a polymer having a heat storage property as disclosed in WO2018/207387A and JP2007-031610A may also be used.

The protective layer may include components other than the resin. Examples of other components include a thermal conductive material, a flame retardant, an ultraviolet absorbing agent, an antioxidant, and a preservative.

The flame retardant is not particularly limited, and known materials can be used. For example, the flame retardant described in “Practical application and technology of flame retardant materials” (published by CMC Publishing Co., Ltd.), and the like can be used, and a halogen-based flame retardant, a phosphorus-based flame retardant, and an inorganic flame retardant are preferably used. In a case in which it is desirable to suppress the mixing of halogen in electronic applications, the phosphorus-based flame retardant and the inorganic flame retardant are preferably used.

Examples of the phosphorus-based flame retardant include phosphate materials such as triphenyl phosphate, tricresyl phosphate, trixylenyl phosphate, cresyl phenyl phosphate, 2-ethylhexyl diphenyl phosphate, other aromatic phosphate esters, aromatic condensed phosphate esters, polyphosphates, phosphinic acid metal salts, and red phosphorus.

It is also preferable to include an auxiliary flame retardant in combination with the flame retardant. Examples of the auxiliary flame retardant include pentaerythritol, phosphorous acid, and 22-oxidized tetrazinc 12-boron heptahydrate.

The thickness of the protective layer is not particularly limited, but it is preferably 50 μm or less, more preferably 0.01 to 25 μm, and further preferably 0.5 to 15 μm.

The thickness is an average value obtained by observing the cut cross section of the protective layer cut in parallel to the thickness direction with SEM, measuring any 5 points, and averaging the thicknesses of the 5 points.

The forming method of the protective layer is not particularly limited, and a known method can be adopted. For example, there are a method in which the protective layer forming composition including a resin or a precursor thereof is brought into contact with the heat storage sheet, and the coating film which is formed on the heat storage sheet is subjected to a hardening treatment as needed, and a method of adhering the protective layer to the heat storage sheet.

Hereinafter, a method of using the protective layer forming composition will be described in detail.

The resin included in the protective layer forming composition is as described above.

The precursor of the resin means a component that becomes a resin by hardening treatment, and examples thereof include a compound represented by Formula (1) as described above.

The protective layer forming composition may include the solvent (for example, water and an organic solvent), as needed.

The method in which the protective layer forming composition is brought into contact with the heat storage sheet is not particularly limited, and for example, there are a method of applying the protective layer forming composition onto the heat storage sheet and a method of immersing the heat storage sheet in the protective layer forming composition.

Examples of the method for applying the protective layer forming composition include a method of using a known coating device such as a dip coater, a die coater, a slit coater, a bar coater, an extrusion coater, a curtain flow coater, spray coating, and the like, and a printing device such as gravure printing, screen printing, offset printing, inkjet printing, and the like.

<Adhesion Layer>

For the purpose of improving the adhesiveness between the heat generating body, which will be described below, and the heat storage sheet, the adhesion layer may be disposed on the surface side of the base material opposite to the heat storage sheet. Examples of the adhesion layer include a pressure sensitive adhesive layer and an adhesive layer.

The material of the pressure sensitive adhesive layer is not particularly limited, and examples thereof include a known pressure sensitive adhesive.

As the pressure sensitive adhesive, for example, there are an acrylic pressure sensitive adhesive, a rubber-based pressure sensitive adhesive, and a silicone-based pressure sensitive adhesive. Further, examples of the pressure sensitive adhesive include the acrylic pressure sensitive adhesive, the ultraviolet hardening pressure sensitive adhesive, the silicone pressure sensitive adhesive, and the like described in “Characteristic evaluation of peeling paper/peeling film and pressure sensitive adhesive tape and its control technology”, published by Johokiko Co., Ltd., 2004, Chapter 2.

The acrylic pressure sensitive adhesive refers to a pressure sensitive adhesive including a polymer ((meth)acrylic polymer) of a (meth)acrylic monomer.

The pressure sensitive adhesive layer may further include a viscosity imparting agent.

The material of the adhesive layer is not particularly limited, and examples thereof include a known adhesive.

Examples of the adhesive include a urethane resin adhesive, a polyester adhesive, an acrylic resin adhesive, an ethylene vinyl acetate resin adhesive, a polyvinyl alcohol adhesive, a polyamide adhesive, and a silicone adhesive.

The forming method of the adhesion layer is not particularly limited, and for example, there are a method of transferring the adhesion layer onto the heat storage sheet and a method of applying the composition which includes the pressure sensitive adhesive or the adhesive onto the heat storage sheet to form the adhesion layer.

The thickness of the adhesion layer is not particularly limited, but it is preferably 0.5 to 100 μm, more preferably 1 to 25 μm, and further preferably 1 to 15 μm.

<Flame Retardant Layer>

The heat storage member may include a flame retardant layer. The position of the flame retardant layer is not particularly limited, and it may be integrated with the protective layer or may be provided as a separate layer. In a case in which it is provided as a separate layer, it is preferable that the flame retardant layer be stacked between the protective layer and the heat storage sheet. A case in which it is integrated with the protective layer means that the protective layer has a flame retardant function. In particular, in a case in which the latent heat storage material is a flammable material such as paraffin, the entire heat storage member can be made to have flame retardance by including a flame retardant protective layer or a flame retardant layer.

The flame retardant protective layer and the flame retardant layer are not particularly limited as long as the layers have the flame retardance, but it is preferable that the layers be formed of a flame retardant organic resin such as a polyetheretherketone resin, a polycarbonate resin, a silicone resin, and a fluorine-containing resin, and an inorganic material such as a glass film, and the like. Where, the glass film can be formed by, for example, applying a silane coupling agent or a siloxane oligomer onto the heat storage sheet, and heating or drying the agent.

As a forming method of the flame retardant protective layer, a flame retardant may be mixed in the resin of the protective layer to form the flame retardant protective layer. As an example of the flame retardant, the flame retardant described above and inorganic particles such as silica are preferably adopted. The amount and type of inorganic particles can be adjusted, including the type of a resin, depending on the surface shape and/or film quality. The size of the inorganic particle is preferably 0.01 to 1 μm, more preferably 0.05 to 0.3 μm, and further preferably 0.1 to 0.2 μm.

The content of the inorganic particles to the total mass of the protective layer is preferably 0.1% to 50% by mass, and more preferably 1% to 40% by mass.

From the viewpoints of the amount of heat storage and the flame retardance, the content of the flame retardant to the total mass of the protective layer is preferably 0.1% to 20% by mass, more preferably 1% to 15% by mass, and further preferably 1% to 5% by mass. Further, from the viewpoints of the amount of heat storage and the flame retardance, the thickness of the flame retardant protective layer is preferably 0.1 to 20 μm, more preferably 0.5 to 15 μm, and further preferably 0.5 to 10 μm.

<Coloration Layer>

The heat storage member may include a coloration layer. By providing the coloration layer, it is possible to suppress the tint change of the appearance of the heat storage member even in a case in which the tint of the heat storage sheet changes. In addition, rubbing when handling it or intrusion of water or the like into the heat storage sheet can be suppressed, and physical or chemical changes in the microcapsule can be suppressed, as a result, tint change of the heat storage sheet itself can be suppressed.

The coloration layer may be integrated with the protective layer, or may be disposed as a separate layer so as to be in contact with the heat storage sheet.

It is preferable that the coloration layer include a coloring agent in order to obtain the desired color tone.

Examples of the coloring agent include a pigment and a dye, and the pigment is preferable, the black pigment is more preferable, and the carbon black is further preferable, from the viewpoints of excellent weather fastness and being capable of suppressing the tint change of the appearance of the heat storage member. In a case in which the carbon black is used, the thermal conductivity of the coloration layer is further improved.

Examples of the pigment include various known inorganic pigments and organic pigments in the related art.

Specific examples of the inorganic pigment include the white pigment such as titanium dioxide, zinc oxide, lithopone, light calcium carbonate, white carbon, aluminum oxide, aluminum hydroxide, barium sulfate, and the like, and the black pigment such as carbon black, titanium black, and titanium carbon, iron oxide, graphite, and the like.

Examples of the organic pigment include the organic pigment disclosed in paragraph 0093 of JP2009-256572A.

Examples of the organic pigment include a red pigment such as C. I. Pigment Red 177, 179, 224, 242, 254, 255, 264, and the like, a yellow pigment such as C. I. Pigment Yellow 138, 139, 150, 180, 185, and the like, an orange pigment such as C. I. Pigment Orange 36, 38, 71, and the like, a green pigment such as C. I. Pigment Green 7, 36, 58, and the like, a blue pigment such as C. I. Pigment Blue 15: 6 and the like, and a violet pigment such as C. I. Pigment Violet 23.

The coloring agent may be used alone, or two types or more may be used.

The content of the coloring agent (for example, black pigment) in the coloration layer is not particularly limited, but from the viewpoint of being capable of suppressing the tint change of the appearance of the heat storage member, it is preferably 2% to 30% by volume, and more preferably 5% to 25% by volume based on the total volume of the coloration layer.

The coloration layer may include the binder.

The type of the binder is not particularly limited, and a known material can be adopted, and a resin is preferable.

As the resin, resin selected from the group consisting of fluororesin and siloxane resin is preferable from the viewpoint of further improving water resistance and flame retardance. By including the resin selected from the group consisting of fluororesin and siloxane resin, which has good water resistance, in the coloration layer, it is possible to suppress the chemical change of the microcapsule and to suppress the tint change of the heat storage sheet.

Specific examples of the fluororesin and the siloxane resin are described above.

The content of the binder in the coloration layer is not particularly limited, but from the viewpoint of being capable of suppressing the tint change of the appearance of the heat storage member, it is preferably 50% to 98% by volume, and more preferably 75% to 95% by volume based on the total volume of the coloration layer.

The binder in the coloration layer may be used alone, or two types or more may be used.

The coloration layer may include components other than the coloring agent and the binder. Examples of other components include a thermal conductive material, a flame retardant, an ultraviolet absorbing agent, an antioxidant, and a preservative.

The thickness of the coloration layer is not particularly limited, but it is preferably 0.1 to 100 μm, and more preferably 0.5 to 10 μm.

The thickness is an average value obtained by observing the cut cross section of the coloration layer cut in parallel to the thickness direction with SEM, measuring any 5 points, and averaging the thicknesses of the 5 points.

One of the suitable embodiments of the coloration layer is an embodiment in which the film thickness of the coloration layer is 15 μm or less and the optical density of the coloration layer is 1.0 or more. In a case in which the optical density is in the above range, even in a case in which the coloration layer is thin, the tint change of the appearance of the heat storage member can be further suppressed.

It is preferable that the optical density be 1.2 or more. The upper limit is not particularly limited, but it is preferably 6.0 or less.

As the measurement method of the optical density, by using X-rite eXact (manufactured by X-Rite Inc.), the optical density is measured at the density status of ISO status T and D50/2° without a filter. As the optical density, a K value is adopted as an optical density (OD) value of Xrite.

The forming method of the coloration layer is not particularly limited, and a known method can be adopted. For example, there is a method in which a coloration layer forming composition including the coloring agent and the binder or a precursor thereof is brought into contact with the heat storage sheet, and the coating film which is formed on the heat storage sheet is subjected to a hardening treatment as needed.

The method will be described below in detail.

The coloring agent and the binder included in the coloration layer forming composition are as described above.

The precursor of the binder included in the coloration layer forming composition means a component that becomes the binder by hardening treatment, and examples thereof include a compound represented by Formula (1) as described above.

The coloration layer forming composition may include the solvent (for example, water and an organic solvent), as needed.

The method in which the coloration layer forming composition is brought into contact with the heat storage sheet is not particularly limited, and for example, there are a method of applying the coloration layer forming composition onto the heat storage sheet and a method of immersing the heat storage sheet in the coloration layer forming composition.

The method of applying the coloration layer forming composition is the same as the method described in the method of applying the protective layer forming composition.

The coloration layer may be provided on the entire surface of the heat storage sheet, or may be partially provided in a pattern.

<Other Members>

The heat storage member may include a base material which is disposed on a surface side of the heat storage sheet opposite to the protective layer in the heat storage sheet, an adhesion layer which is disposed on a surface side of the base material opposite to the heat storage sheet, and a temporary base material which is disposed on a surface side of the adhesion layer opposite to the base material. As a result, the damage to the heat storage sheet can be suppressed in a case of storage and transporting of the heat storage member.

The base material and the adhesion layer are as described above. Further, the specific examples of the temporary base material are the same as the specific examples of the base material. The base material which has a peeled surface is preferable.

In a case in which the heat storage member is used, the temporary base material is peeled off from the heat storage member.

[Electronic Device]

The electronic device according to the embodiment of the present invention includes the heat storage member described above, and the heat generating body.

The heat storage members (heat storage sheet, adhesion layer, and protective layer) are as described above.

<Heat Generating Body>

The heat generating body is a member which may generate heat in the electronic device, and is, for example, systems on a chip (SoC) such as a central processing unit (CPU), a graphics processing unit (GPU), a static random access memory (SRAM), and a radio frequency (RF) device, a camera, a LED package, power electronics, and a battery (in particular, lithium-ion secondary battery).

The heat generating body may be disposed so as to be in contact with the heat storage member, or may be disposed on the heat storage member via another layer (for example, the thermal conduction material which will be described below).

<Thermal Conduction Material>

It is preferable that the electronic device further include the thermal conduction material.

The thermal conduction material refers to a material which has a function of conducting heat which is generated from the heat generating body to another medium.

As the “thermal conductivity” of the thermal conduction material, it is preferable that the thermal conductivity be 10 Wm⁻¹K⁻¹ or more. That is, it is preferable that the thermal conduction material be the material which has the thermal conductivity of 10 Wm⁻¹K⁻¹ or more. The thermal conductivity (unit: Wm⁻¹K⁻¹) is a value measured by a flash method at a temperature of 25° C. by a method compliant with Japanese Industrial Standards (JIS) R1611.

As the thermal conduction material which may be included in the electronic device, for example, there are the metal plate, the heat radiation sheet, silicone grease, and the like, and the metal plate or the heat radiation sheet is preferably used.

It is preferable that the electronic device include the heat storage member, the thermal conduction material which is disposed on the heat storage member, and the heat generating body which is disposed on the surface side of the thermal conductive material opposite to the heat storage member. Further, it is more preferable that the electronic device include the heat storage member, the metal plate which is disposed on the heat storage member, and the heat generating body which is disposed on the surface side of the metal plate opposite to the heat storage member.

In a case in which the heat storage member includes the protective layer, one of the suitable embodiments of the electronic device is to include the heat storage member, a metal plate which is disposed on a surface side of the heat storage member opposite to the protective layer, and the heat generating body which is disposed on a surface side of the metal plate opposite to the heat storage member. Stated another way, it is preferable that the protective layer, the heat storage sheet, the metal plate, and the heat generating body be stacked in this order.

(Metal Plate)

The metal plate has a function of protecting the heat generating body and conducting heat which is generated from the heat generating body to the heat storage sheet.

The surface of the metal plate opposite to the surface on which the heat generating body is provided may be in contact with the heat storage sheet, or the heat storage sheet may be disposed via another layer (for example, the heat radiation sheet, the adhesion layer, or the base material).

Examples of the material configuring the metal plate include aluminum, copper, and stainless steel.

(Heat Radiation Sheet)

The heat radiation sheet is a sheet which has a function of conducting heat which is generated from the heat generating body to another medium, and it is preferable that a heat radiation material be provided. Examples of the heat radiation material include carbon, metal (for example, silver, copper, aluminum, iron, platinum, stainless steel, and nickel), and silicone.

Specific examples of the heat radiation sheet include a copper foil sheet, a metal film resin sheet, a metal-containing resin sheet, and a graphene sheet, and the graphene sheet is preferably used. The thickness of the heat radiation sheet is not particularly limited, but it is preferably 10 to 500 μm, and more preferably 20 to 300 μm.

<Heat Pipe, Vapor Chamber>

It is preferable that the electronic device further include a heat transport member selected from the group consisting of the heat pipe and the vapor chamber.

Both the heat pipe and the vapor chamber are formed of the metal, and comprise at least a member which has a hollow structure and an working fluid which is a heat transfer medium enclosed in the internal space, in which the working fluid evaporates (vaporizes) in a high temperature portion (evaporation portion) and heat is absorbed, and the vaporized working fluid is condensed in a low temperature portion (condensing portion) and heat is radiated. The heat pipe and the vapor chamber have a function of transporting heat from a member in contact with the high temperature portion to a member in contact with the low temperature portion due to a phase change of the working fluid inside.

In a case in which the electronic device includes the heat storage member and the heat transport member selected from the group consisting of the heat pipe and the vapor chamber, it is preferable that the heat storage member and the heat pipe or the vapor chamber be in contact with each other, and it is more preferable that the heat storage member be in contact with the low temperature portion of the heat pipe or the vapor chamber.

Further, in a case in which the electronic device includes the heat storage member and the heat transport member selected from the group consisting of the heat pipe and the vapor chamber, it is preferable that the phase change temperature of the heat storage material included in the heat storage sheet according to the embodiment of the present invention which is included in the heat storage member, and the temperature range in which the heat pipe or the vapor chamber is operated be overlapped. The temperature range in which the heat pipe or the vapor chamber is operated includes, for example, the temperature range in which the working fluid can change a phase in each inside.

The heat pipe has at least a tubular member and the working fluid enclosed in the internal space thereof. It is preferable that the heat pipe have a wick structure on the inner wall of the tubular member, which serves as a flow path for the working fluid based on the capillary phenomenon, and have a cross sectional structure in which the internal space serving as a flow path for the vaporized working fluid is provided inside. The shape of the tubular member is, for example, a circular tubular, a square tubular, and a flat elliptical tubular. The tubular member may include a bending portion. Further, the heat pipe may be a loop heat pipe which has a structure in which tubular members are connected in a loop shape.

The vapor chamber includes at least a flat plate member which has a hollow structure and the working fluid enclosed in the internal space thereof. It is preferable that the vapor chamber have a wick structure similar to that of the heat pipe on the inner surface of the flat plate member. In the vapor chamber, heat is generally transported by absorbing heat from a member in contact with one main surface of the flat plate member and radiating heat to a member in contact with the other main surface.

The materials which configure the heat pipe and the vapor chamber are not particularly limited as long as it is a material which has high thermal conductivity, and examples thereof include a metal such as copper and aluminum.

Examples of the working fluid enclosed in the internal space of the heat pipe and the vapor chamber include water, methanol, ethanol, and CFC substitutes, which are appropriately selected and used depending on the temperature range of the applied electronic device.

<Other Members>

The electronic device may include members other than the protective layer, the heat storage sheet, the thermal conduction material, the heat generating body, and the heat transport member which is described above. Examples of other members include the base material and the adhesion layer. The base material and the adhesion layer are as described above.

The electronic device may have at least one member selected from the group consisting of the heat radiation sheet, the base material, and the adhesion layer between the heat storage sheet and the metal plate. In a case in which two or more members among the heat radiation sheet, the base material, and the adhesion layer are disposed between the heat storage sheet and the metal plate, it is preferable that the base material, the adhesion layer, and the heat radiation sheet be disposed in this order from the heat storage sheet side to the metal plate side.

Further, the electronic device may have the heat radiation sheet between the metal plate and the heat generating body.

The specific examples of the electronic device are as described above, and the description thereof will be omitted.

### EXAMPLES

The present invention will be described below in more detail with reference to Examples. However, the present invention is not limited to the following Examples as long as the gist of the present invention is not exceeded.

### Example 1

(Preparation of Microcapsule Dispersion Liquid) A solution A to which 120 parts by mass of ethyl acetate was added was obtained by heating and dissolving 72 parts by mass of n-icosane (latent heat storage material; an aliphatic hydrocarbon having a melting point of 37° C. and 20 carbon atoms, purity of 99.5%) at 60° C.

Next, a solution B was obtained by adding 0.05 parts by mass of N,N,N′,N′-tetrakis(2-hydroxypropyl)ethylenediamine (Adeka Polyether EDP-300, manufactured by ADEKA CORPORATION) to the solution A being stirred.

Further, a solution C was obtained by adding 4.0 parts by mass of trimethylolpropane adduct (Burnock D-750, manufactured by DIC Corporation) of tolylene diisocyanate dissolved in 1 part by mass of methyl ethyl ketone to the solution B being stirred.

Then, the solution C was added to a solution obtained by dissolving 7.4 parts by mass of polyvinyl alcohol (Kuraray Poval (registered trademark) KL-318 (manufactured by Kuraray Co., Ltd.; polyvinyl alcohol (PVA)) as the binder in 140 parts by mass of water, and the mixture was emulsified and dispersed. 250 parts by mass of water were added to the emulsified liquid after emulsification and dispersion, the mixture was heated to 70° C. while stirring the obtained solution, and then cooled to 30° C. after continuing stirring for 1 hour. Water was further added to the cooled liquid to adjust the concentration, and a dispersion liquid of the n-icosane encapsulating microcapsule, which has a polyurethane urea capsule wall was obtained. A concentration of solid contents of the dispersion liquid was 14% by mass.

Kuraray Poval KL-318 used as the polyvinyl alcohol is modified polyvinyl alcohol which has a carboxy group or a salt thereof as a modified group.

The volume-based median diameter Dm of the microcapsule in the obtained dispersion liquid was 20 μm. Further, the thickness 6 of the capsule wall of the microcapsule was 0.1 μM.

Further, the deformation rate of the microcapsule extracted from the obtained dispersion liquid was measured by the above method by using an HM2000 type micro hardness meter manufactured by FISCHER INSTRUMENTS K. K. as an indentation type hardness meter, as a result, the deformation rate of the microcapsules was 41%.

(Preparation of Heat Storage Sheet Forming Composition)

By adding and mixing 1.5 parts by mass of a side chain alkylbenzene sulfonic acid amine salt (NEOGEN T, manufactured by DKS Co., Ltd.), 0.15 parts by mass of 1,2-bis(3,3,4,4,5,5,6,6,6-nonafluorohexyloxycarbonyl) sodium ethanesulfonate (W-AHE, manufactured by FUJIFILM Corporation), and 0.15 parts by mass of polyoxyalkylene alkyl ether (Noigen LP-90, manufactured by DKS Co., Ltd.) to 1000 parts by mass of the obtained microcapsule dispersion liquid, and a heat storage sheet forming composition 1 was obtained.

(Manufacturing of Polyethylene Terephthalate (PET) Base Material (A) with Easily Adhesive Layer and Pressure Sensitive Adhesive Layer)

An optical pressure sensitive adhesive sheet MO-3015 (thickness: 5 μm) manufactured by LINTEC Corporation was attached to the PET base material which has a thickness of 6 μm to form the pressure sensitive adhesive layer.

An aqueous solution in which Nipol Latex LX407C4E (manufactured by Zeon Corporation), Nipol Latex LX407C4C (manufactured by Zeon Corporation), and Aquabrid EM-13 (manufactured by Daicel Fine Chem Ltd.) were mixed and dissolved such that the concentration of solid contents was 22:77.5:0.5 (mass-based) was applied on the surface of the PET base material opposite to the surface including the pressure sensitive adhesive layer, and dried at 115° C. for 2 minutes to form the easily adhesive layer formed of a styrene-butadiene rubber resin which has a thickness of 1.3 μm and prepare a PET base material (A) with the easily adhesive layer and the pressure sensitive adhesive layer.

(Manufacturing of Heat Storage Member 1)

The heat storage sheet forming composition 1 was applied to the surface of the easily adhesive layer of the PET base material (A) with the easily adhesive layer and the pressure sensitive adhesive layer by a bar coater such that the mass after drying was 172 g/m², dried at 80° C. for 25 minutes, and was allowed to stand in the constant-temperature and constant-humidity tank at 50% RH and 25° C. for 2 hours to form a heat storage sheet 1 on the PET base material.

In a case in which the content of water in the heat storage sheet after drying and before being allowed to stand in the constant-temperature and constant-humidity tank was measured according to the above method, the content of water in the heat storage sheet to the total mass of the heat storage sheet was 10% by mass. Also, in a case in which the content of water in the heat storage sheet after being allowed to stand in the constant-temperature and constant-humidity tank was measured in the same manner, the content of water in the heat storage sheet to the total mass of the heat storage sheet was less than 1% by mass. The thickness of the layer formed of the heat storage sheet forming composition 1 was 190 μm.

The content of the microcapsule in the heat storage sheet to the total mass of the heat storage sheet was 91% by mass or more. The content of the heat storage material (n-icosane) in the heat storage sheet to the total mass of the heat storage sheet was 85% by mass.

### Example 2

A heat storage sheet 2 was formed and a heat storage member 2 was manufactured according to the same procedure as in Example 1 except that the drying conditions after application of the heat storage sheet forming composition were changed to 90° C. for 20 minutes.

In addition, both the content of water in the heat storage sheet after drying and before being allowed to stand in the constant-temperature and constant-humidity tank, and the content of water in the heat storage sheet after being allowed to stand in the constant-temperature and constant-humidity tank were the same as in Example 1.

### Example 3

A heat storage sheet 3 was formed and a heat storage member 3 was manufactured according to the same procedure as in Example 1 except that the drying conditions after application of the heat storage sheet forming composition were changed to 100° C. for 15 minutes.

In addition, both the content of water in the heat storage sheet after drying and before being allowed to stand in the constant-temperature and constant-humidity tank, and the content of water in the heat storage sheet after being allowed to stand in the constant-temperature and constant-humidity tank were the same as in Example 1.

### Example 4

The amount of N,N,N′,N′-tetrakis(2-hydroxypropyl)ethylenediamine and the amount of trimethylolpropane adduct of tolylene diisocyanate, which were used in “Preparation of Microcapsule Dispersion Liquid” of Example 1, were changed from 0.05 parts by mass to 0.025 parts by mass, and from 4.0 parts by mass to 2.0 parts by mass, respectively.

Also, the drying conditions after application of the heat storage sheet forming composition were changed to 100° C. for 15 minutes.

Except for these conditions, a heat storage sheet 4 was formed and a heat storage member 4 was manufactured according to the same procedure as in Example 1.

In addition, both the content of water in the heat storage sheet after drying and before being allowed to stand in the constant-temperature and constant-humidity tank, and the content of water in the heat storage sheet after being allowed to stand in the constant-temperature and constant-humidity tank were the same as in Example 1.

### Example 5

The amount of polyvinyl alcohol, which was used in “Preparation of Microcapsule Dispersion Liquid” of Example 1, was changed from 7.4 parts by mass to 14.8 parts by mass.

Also, the drying conditions after application of the heat storage sheet forming composition were changed to 90° C. for 20 minutes.

Except for these conditions, a heat storage sheet 5 was formed and a heat storage member 5 was manufactured according to the same procedure as in Example 1.

In addition, both the content of water in the heat storage sheet after drying and before being allowed to stand in the constant-temperature and constant-humidity tank, and the content of water in the heat storage sheet after being allowed to stand in the constant-temperature and constant-humidity tank were the same as in Example 1.

### Example 6

The type of polyvinyl alcohol, which was used in “Preparation of Microcapsule Dispersion Liquid” of Example 1, was changed to Kuraray Poval (registered trademark) 45-88 (manufactured by Kuraray Co., Ltd; PVA).

Also, the drying conditions after application of the heat storage sheet forming composition were changed to 90° C. for 20 minutes.

Except for these conditions, a heat storage sheet 6 was formed and a heat storage member 6 was manufactured according to the same procedure as in Example 1.

In addition, both the content of water in the heat storage sheet after drying and before being allowed to stand in the constant-temperature and constant-humidity tank, and the content of water in the heat storage sheet after being allowed to stand in the constant-temperature and constant-humidity tank were the same as in Example 1.

Kuraray Poval 45-88 used as the polyvinyl alcohol is unmodified polyvinyl alcohol which is partially saponified.

### Example 7

The type of polyvinyl alcohol, which was used in “Preparation of Microcapsule Dispersion Liquid” of Example 1, was changed to GOHSENX (registered trademark) Z320 (manufactured by Mitsubishi Chemical Corporation; PVA).

Also, the drying conditions after application of the heat storage sheet forming composition were changed to 90° C. for 20 minutes.

Except for these conditions, a heat storage sheet 7 was formed and a heat storage member 7 was manufactured according to the same procedure as in Example 1.

In addition, both the content of water in the heat storage sheet after drying and before being allowed to stand in the constant-temperature and constant-humidity tank, and the content of water in the heat storage sheet after being allowed to stand in the constant-temperature and constant-humidity tank were the same as in Example 1.

The GOHSENX (registered trademark) Z320 used as the polyvinyl alcohol is modified polyvinyl alcohol which has an acetoacetyl group as a modified group.

### Example 8

A heat storage sheet 8 was formed and a heat storage member 8 was manufactured in the same manner as in Example 6 except that Kuraray Poval 45-88 was changed Kuraray Poval 25-88E.

The Kuraray Poval 25-88E used as the polyvinyl alcohol is unmodified polyvinyl alcohol which is partially saponified.

### Example 9

A heat storage sheet 9 was formed on the easily adhesive layer of the PET base material (A) with the easily adhesive layer and the pressure sensitive adhesive layer in the same manner as in Example 1 except that the drying conditions after application of the heat storage sheet forming composition were changed to 100° C. for 12 minutes. Then, a protective layer forming composition 1 described below was applied onto the easily adhesive layer of the heat storage sheet 9 and dried under the drying condition at 60° C. for 2 minutes to form a protective layer 1. A film thickness of the protective layer 1 was 3 μm. This was defined as a heat storage member 9.

(Preparation of Protective Layer Forming Composition 1)

The components as follows were mixed to prepare a protective layer forming composition 1.

24.2 parts by mass of KYNAR Aquatec ARC (manufactured by Arkema, 44% by mass of concentration of solid contents; fluororesin)

21.4 parts by mass of Epocros WS-700 (manufactured by Nippon Shokubai Co., Ltd., 25% by mass of concentration of solid contents; hardening agent)

33.2 parts by mass of FUJI JET BLACK B-15 (manufactured by Fuji Pigment Co., Ltd., 15% by mass of concentration of solid contents, carbon black)

20.0 parts by mass of Taien E (manufactured by Taihei Chemical Industrial Co., Ltd.; flame retardant, diluted in water dispersion liquid which has 20% by mass of a concentration of solid contents)

1.2 parts by mass of Noigen LP-70 (manufactured by DKS Co., Ltd. (diluted in an aqueous solution with 2% by mass of the concentration of solid contents); surfactant)

### Example 10

A heat storage sheet 10 and a protective layer 2 were formed and a heat storage member 10 was manufactured in the same manner as in Example 9 except that the protective layer forming composition 1 was changed to a protective layer forming composition 2.

(Preparation of Protective Layer Forming Composition 2)

The components as follows were mixed to prepare a protective layer forming composition 2.

4.3 parts by mass of pure water

0.4 parts by mass of 1M sodium hydroxide aqueous solution

47.2 parts by mass of X-12-1098 (manufactured by Shin-Etsu Chemical Co., Ltd., 30% by mass of concentration of solid contents)

15.2 parts by mass of Snowtex XL (manufactured by Nissan Chemical Corporation, 40% by mass of concentration of solid contents, silica particle, 60 nm of average particle diameter)

31.7 parts by mass of FUJI JET BLACK B-15 (manufactured by Fuji Pigment Co., Ltd., 15% by mass of concentration of solid contents, carbon black)

1.2 parts by mass of Noigen LP-70 (manufactured by DKS Co., Ltd. (diluted in an aqueous solution with 2% by mass of the concentration of solid contents); surfactant)

### Example 11

A heat storage sheet 11 and a protective layer 3 were formed and a heat storage member 11 was manufactured in the same manner as in Example 9 except that the protective layer forming composition 1 was changed to a protective layer forming composition 3.

(Preparation of Protective Layer Forming Composition 3)

The components as follows were mixed to prepare a protective layer forming composition 3.

11.4 parts by mass of KYNAR Aquatec ARC (manufactured by Arkema, 44% by mass of concentration of solid contents; fluororesin)

10.1 parts by mass of Epocros WS-700 (manufactured by Nippon Shokubai Co., Ltd., 25% by mass of concentration of solid contents; hardening agent)

15.63 parts by mass of FUJI JET BLACK B-15 (manufactured by Fuji Pigment Co., Ltd., 15% by mass of concentration of solid contents, carbon black)

15.6 parts by mass of Taien E (manufactured by Taihei Chemical Industrial Co., Ltd.; flame retardant, diluted in water dispersion liquid which has 20% by mass of a concentration of solid contents) (0.4 μm of median diameter (prepared by pulverization with glass beads))

11.7 parts by mass of Noigen LP-70 (manufactured by DKS Co., Ltd. (diluted in an aqueous solution with 0.5% by mass of the concentration of solid contents); surfactant)

11.7 parts by mass of 1,2-bis(3,3,4,4,5,5,6,6,6-nonafluorohexyloxycarbonyl) sodium ethanesulfonate (W-AHE, manufactured by FUJIFILM Corporation) (diluted in an aqueous solution with 0.5% by mass of the concentration of solid contents; surfactant)

30.1 parts by mass of pure water

### Example 12

A heat storage sheet 12 and a protective layer 4 were formed and a heat storage member 12 was manufactured according to the same procedure as in Example 1 except that the heat storage sheet forming composition 1 was applied such that the mass after drying was 143 g/m² and dried at 100° C. for 10 minutes, then the heat storage sheet forming composition 1 (mass after drying was 29 g/m²) and a protective layer forming composition 4 (dry film thickness was 3 μm) were applied and dried at 45° C. for 2 minutes.

(Preparation of Protective Layer Forming Composition 4)

The components as follows were mixed to prepare the protective layer forming composition 4.

16.3 parts by mass of KYNAR Aquatec ARC (manufactured by Arkema, 44% by mass of concentration of solid contents; fluororesin)

14.4 parts by mass of Epocros WS-700 (manufactured by Nippon Shokubai Co., Ltd., 25% by mass of concentration of solid contents; hardening agent)

22.4 parts by mass of FUJI JET BLACK B-15 (manufactured by Fuji Pigment Co., Ltd., 15% by mass of concentration of solid contents, carbon black)

13.5 parts by mass of Taien E (manufactured by Taihei Chemical Industrial Co., Ltd.; flame retardant, diluted in water dispersion liquid which has 20% by mass of a concentration of solid contents) (0.4 μm of median diameter (prepared by pulverization with glass beads))

16.7 parts by mass of Noigen LP-70 (manufactured by DKS Co., Ltd. (diluted in an aqueous solution with 0.5% by mass of the concentration of solid contents); surfactant)

16.7 parts by mass of 1,2-bis(3,3,4,4,5,5,6,6,6-nonafluorohexyloxycarbonyl) sodium ethanesulfonate (W-AHE, manufactured by FUJIFILM Corporation) (diluted in an aqueous solution with 0.5% by mass of the concentration of solid contents; surfactant)

### Example 13

The heat storage sheet and the heat storage member were manufactured in the same manner as in Example 1 except that the rotation speed in a case of emulsification and dispersion was increased and the time was changed to be longer in a preparing step of the dispersion liquid of the n-icosane encapsulating microcapsule.

### Example 14

The heat storage sheet and the heat storage member were manufactured in the same manner as in Example 1 except that the rotation speed in a case of emulsification and dispersion was reduced and the time was changed to be shorter in a preparing step of the dispersion liquid of the n-icosane encapsulating microcapsule.

### Example 15

The heat storage sheet and the heat storage member were manufactured in the same manner as in Example 1 except that the amount of N,N,N′,N′-tetrakis(2-hydroxypropyl)ethylenediamine and the amount of trimethylolpropane adduct of tolylene diisocyanate, which were used in “Preparation of Microcapsule Dispersion Liquid” of Example 1, were changed to 0.082 parts by mass, and to 6.5 parts by mass, respectively, and the rotation speed in a case of emulsification and dispersion was increased and the time was changed to be longer in the preparing step of the dispersion liquid of the n-icosane encapsulating microcapsule.

### Example 16

The heat storage sheet and the heat storage member were manufactured in the same manner as in Example 1 except that the amount of N,N,N′,N′-tetrakis(2-hydroxypropyl)ethylenediamine and the amount of trimethylolpropane adduct of tolylene diisocyanate, which were used in “Preparation of Microcapsule Dispersion Liquid” of Example 1, were changed to 0.054 parts by mass, and to 4.3 parts by mass, respectively, and the rotation speed in a case of emulsification and dispersion was increased and the time was changed to be longer in the preparing step of the dispersion liquid of the n-icosane encapsulating microcapsule.

### Example 17

The heat storage sheet and the heat storage member were manufactured in the same manner as in Example 1 except that the amount of N,N,N′,N′-tetrakis(2-hydroxypropyl)ethylenediamine and the amount of trimethylolpropane adduct of tolylene diisocyanate, which were used in “Preparation of Microcapsule Dispersion Liquid” of Example 1, were changed to 0.045 parts by mass, and to 3.6 parts by mass, respectively, and the rotation speed in a case of emulsification and dispersion was reduced and the time was changed to be shorter in the preparing step of the dispersion liquid of the n-icosane encapsulating microcapsule.

### Example 18

The heat storage sheet and the heat storage member were manufactured in the same manner as in Example 1 except that the amount of N,N,N′,N′-tetrakis(2-hydroxypropyl)ethylenediamine and the amount of trimethylolpropane adduct of tolylene diisocyanate, which were used in “Preparation of Microcapsule Dispersion Liquid” of Example 1, were changed to 0.068 parts by mass, and to 5.5 parts by mass, respectively, and the rotation speed in a case of emulsification and dispersion was reduced and the time was changed to be shorter in the preparing step of the dispersion liquid of the n-icosane encapsulating microcapsule.

### Example 19

The heat storage sheet and the heat storage member were manufactured in the same manner as in Example 3 except that the rotation speed in a case of emulsification and dispersion was increased and the time was changed to be longer in a preparing step of the dispersion liquid of the n-icosane encapsulating microcapsule.

### Comparative Example 1

The amount of N,N,N′,N′-tetrakis(2-hydroxypropyl)ethylenediamine and the amount of trimethylolpropane adduct of tolylene diisocyanate, which were used in “Preparation of Microcapsule Dispersion Liquid” of Example 1, were changed from 0.05 parts by mass to 0.1 parts by mass, and from 4.0 parts by mass to 8.0 parts by mass, respectively.

Except for these conditions, a heat storage sheet C1 was formed and a heat storage member C1 was manufactured according to the same procedure as in Example 1.

In addition, both the content of water in the heat storage sheet after drying and before being allowed to stand in the constant-temperature and constant-humidity tank, and the content of water in the heat storage sheet after being allowed to stand in the constant-temperature and constant-humidity tank were the same as in Example 1.

### Comparative Example 2

A heat storage sheet C2 was formed and a heat storage member C2 was manufactured according to the same procedure as in Example 1 except that the drying conditions after application of the heat storage sheet forming composition were changed to 30° C. for 180 minutes.

In addition, both the content of water in the heat storage sheet after drying and before being allowed to stand in the constant-temperature and constant-humidity tank, and the content of water in the heat storage sheet after being allowed to stand in the constant-temperature and constant-humidity tank were the same as in Example 1.

<Evaluation>

The following evaluation was performed. The evaluation results are shown in Table 1 below.

Further, for Examples 2 to 19 and Comparative Examples 1 and 2, the volume-based median diameter Dm of the microcapsule, the thickness δ of the capsule wall of the microcapsule, the ratio (δ/Dm) of the thickness δ of the capsule wall of the microcapsule to the volume-based median diameter Dm of the microcapsule, and the deformation rate of the microcapsule are shown in Table 1, which are measured according to the same procedure as in Example 1.

In Examples 8 to 19, the content of water in the heat storage sheet after being allowed to stand in the constant-temperature and constant-humidity tank was 5% by mass or less based on the total mass of the heat storage sheet.

(Measurement of Void Volume)

By using the X-ray CT apparatus, the void volume of the heat storage sheet was calculated according to the method described above.

The void volume was analyzed by using the X-ray CT apparatus only for the heat storage sheet portion by using the heat storage member (that is, the measurement was performed without peeling off the heat storage sheet from the heat storage member).

(Measurement of Adjacency Ratio of Microcapsule)

The adjacency ratio of the microcapsule of the heat storage sheet was calculated according to the method described above.

The adjacency ratio of the microcapsule was obtained from the SEM cross sectional image of the heat storage sheet portion in the obtained slice by cutting the heat storage member along the normal direction of the main surface such that the shape and disposition of the microcapsule were maintained (that is, the measurement was performed without peeling off the heat storage sheet from the heat storage member).

(Measurement of Latent Heat Capacity)

The latent heat capacity of the heat storage sheet which was obtained was calculated from the result of the differential scanning calorimetry and the thickness of the heat storage sheet.

The latent heat capacity of the heat storage sheet was calculated by measuring the latent heat capacity of the heat storage member, and then subtracting the thickness and mass of the base material and the protective layer.

The latent heat capacity of the heat storage member was also shown in the table.

(Measurement of Defects)

A measurement sample was prepared by cutting the heat storage member into 24 mm×50 mm. In a case in which 1 cm on both sides of the short side of the measurement sample was grasped and extended by 1 cm along the long side direction of the measurement sample, the way of defects (cracks and breaks) in the heat storage sheet was visually observed.

1: No cracks and breaks are seen, or one crack and/or break is observed

2: Two or more cracks and/or breaks are observed, but few

3: Many cracks and/or breaks

(Measurement of Modulus of Tensile Elasticity)

A measurement sample was prepared by cutting the heat storage member into 24 mm×50 mm. The stress in a case in which both ends of the measurement sample were extended along the long side direction was measured according to JIS K 7161-1: 2014, and the range in which the stress changes linearly with respect to the strain was obtained by dividing the slope by the cross-sectional area.

(Measurement of Adhesion)

according to the JIS-Z0237 standard, a test sheet was disposed on the bright annealed (BA) finish steel use stainless (SUS) 304 base material such that the pressure sensitive adhesive layer was in contact with the base material, a roller having a load of 2 kg was pressed from the test sheet, and the SUS 304 base material adhered to the test sheet. After 1 minute had passed from the adhering, the test sheet was peeled off from the SUS 304 base material under the conditions of 180° of peeling and 300 mm/min. The force required to peel off the test sheet was defined as the adhesion (N/mm).

TABLE 1

| | | | Example 1 | Example 2 | Example 3 | Example 4 | Example 5 | Example 6 |
|---|---|---|---|---|---|---|---|---|
| Binder | Type | | Kuraray | Kuraray | Kuraray | Kuraray | Kuraray | Kuraray |
| | | | Poval | Poval | Poval | Poval | Poval | Poval 45-88 |
| | | | KL-318 | KL-318 | KL-318 | KL-318 | KL-318 | |
| | Degree of | | 1800 | 1800 | 1800 | 1800 | 1800 | 2400 |
| | polymerization | | | | | | | |
| | Amount (mass% in heat | | 8.9 | 8.9 | 8.9 | 8.9 | 16.3 | 8.9 |
| | storage sheet) | | | | | | | |
| Microcapsule | Particle diameter Dm | | 20 | 20 | 20 | 20 | 20 | 20 |
| | (μm) | | | | | | | |
| | Wall thickness | | 0.1 | 0.1 | 0.1 | 0.05 | 0.1 | 0.1 |
| | | | 0.005 | 0.005 | 0.005 | 0.0025 | 0.005 | 0.005 |
| | Deformation rate (%) | | 41 | 41 | 41 | 50 | 41 | 41 |
| Protective layer | | | Absence | Absence | Absence | Absence | Absence | Absence |
| Drying | Drying temperature | | 80 | 90 | 100 | 100 | 90 | 90 |
| condition (heat | Drying time | | 25 | 20 | 15 | 15 | 20 | 20 |
| storage sheet) | | | | | | | | |
| Evaluation | Void volume (% by | | 7.0 | 3.5 | 2.0 | 0.3 | 2.0 | 3.0 |
| result | volume) | | | | | | | |
| | Adjacency ratio (%) | | 89.7 | 95.0 | 97.2 | 99.6 | 97.2 | 95.8 |
| | Latent heat | (J/g) | 203 | 203 | 203 | 209 | 203 | 203 |
| | capacity (only | (J/ml) | 172 | 178 | 181 | 187 | 181 | 179 |
| | heat storage sheet | | | | | | | |
| | portion) | | | | | | | |
| | Latent heat | (J/g) | 195 | 195 | 195 | 200 | 195 | 195 |
| | capacity (entire | (J/ml) | 162 | 168 | 170 | 176 | 170 | 168 |
| | member) | | | | | | | |
| | Defect | | 2 | 2 | 1 | 1 | 1 | 2 |
| | Modulus of elasticity | | 2300 | 3300 | 3700 | 4600 | 4100 | 4050 |
| | (MPa) | | | | | | | |
| | Adhesion (N/mm) | | 0.47 | 0.5 | 0.52 | 0.54 | 0.53 | 0.52 |
| | | | Example 7 | Example 8 | Example 9 | Example 10 | Example 11 | Example 12 |
| Binder | Type | | GOHSEN | Kuraray | Kuraray | Kuraray | Kuraray | Kuraray |
| | | | X Z320 | Poval | Poval | Poval | Poval | Poval |
| | | | | 25-88E | KL-318 | KL-318 | KL-318 | KL-318 |
| | Degree of | | 1700 | 1700 | 1800 | 1800 | 1800 | 1800 |
| | polymerization | | | | | | | |
| | Amount (mass% in heat | | 8.9 | 8.9 | 8.9 | 8.9 | 8.9 | 8.9 |
| | storage sheet) | | | | | | | |
| Microcapsule | Particle diameter Dm | | 20 | 20 | 20 | 20 | 20 | 20 |
| | (μm) | | | | | | | |
| | Wall thickness δ (μm) | | 0.1 | 0.1 | 0.1 | 0.1 | 0.1 | 0.1 |
| | δ/Dm | | 0.005 | 0.005 | 0.005 | 0.005 | 0.005 | 0.005 |
| | Deformation rate (%) | | 41 | 41 | 41 | 41 | 41 | 41 |
| Protective layer | | | Absence | Absence | Presence | Presence | Presence | Presence |
| Drying | Drying temperature | | 90 | 90 | 100 | 100 | 100 | 100 |
| condition (heat | Drying time | | 20 | 20 | 12 | 12 | 12 | 10 |
| storage sheet) | | | | | | | | |
| Evaluation | Void volume (% by | | 2.0 | 4.0 | 6.0 | 6.2 | 2.1 | 0.5 |
| result | volume) | | | | | | | |
| | Adjacency ratio (%) | | 97.2 | 94.3 | 91.2 | 90.9 | 97.1 | 99.3 |
| | Latent heat | (J/g | 203 | 203 | 203 | 203 | 203 | 203 |
| | capacity (only | (J/ml) | 181 | 177 | 173 | 171 | 181 | 186 |
| | heat storage sheet | | | | | | | |
| | portion) | | | | | | | |
| | Latent heat | (J/g) | 195 | 195 | 190 | 190 | 191 | 191 |
| | capacity (entire | (J/ml) | 170 | 167 | 161 | 160 | 167 | 170 |
| | member) | | | | | | | |

| | | | | | | |
|---|---|---|---|---|---|---|
| Defect | 1 | 2 | 2 | 2 | 1 | 1 |
| Modulus of elasticity | 3958 | 3900 | 2600 | 2500 | 3700 | 3900 |
| (MPa) | | | | | | |
| Adhesion (N/mm) | 0.52 | 0.51 | 0.56 | 0.55 | 0.58 | 0.58 |

TABLE 2

| | | | Example 13 | Example 14 | Example 15 | Example 16 | Example 17 |
|---|---|---|---|---|---|---|---|
| Binder | Type | | Kuraray Poval | Kuraray Poval | Kuraray Poval | Kuraray Poval | Kuraray Poval |
| | | | KL-318 | KL-318 | KL-318 | KL-318 | KL-318 |
| | Degree of polymerization | | 1800 | 1800 | 1800 | 1800 | 1800 |
| | Amount(mass% in heat | | 8.9 | 8.9 | 8.9 | 8.9 | 8.9 |
| | storage sheet) | | | | | | |
| Microcapsule | Particle diameter Dm (μm) | | 18.5 | 22 | 18.5 | 18.5 | 22 |
| | Wall thickness δ (μm) | | 0.092 | 0.11 | 0.15 | 0.1 | 0.1 |
| | δ/Dm | | 0.005 | 0.005 | 0.008 | 0.005 | 0.005 |
| | Deformation rate (%) | | 46 | 35 | 34 | 44 | 37 |
| Protective layer | | | Absence | Absence | Absence | Absence | Absence |
| Drying | Drying temperature | | 80 | 80 | 80 | 80 | 80 |
| condition (heat | Drying time | | 25 | 25 | 25 | 25 | 25 |
| storage sheet) | | | | | | | |
| Evaluation | Void volume (% by volume) | | 4.0 | 8.5 | 8.6 | 5.0 | 7.9 |
| result | Adjacency ratio (%) | | 94.3 | 87.3 | 87.1 | 89.7 | 88.3 |
| | Latent heat | (J/g) | 203 | 203 | 200 | 202 | 204 |
| | capacity (only | (J/ml) | 177 | 169 | 167 | 175 | 171 |
| | heat storage sheet | | | | | | |
| | portion) | | | | | | |
| | Latent heat | (J/g) | 195 | 195 | 191 | 194 | 196 |
| | capacity (entire | (J/ml) | 167 | 159 | 150 | 165 | 163 |
| | member) | | | | | | |

| | | | | | |
|---|---|---|---|---|---|
| Defect | 2 | 2 | 2 | 2 | 2 |
| Modulus of elasticity (MPa) | 2900 | 1900 | 2000 | 2500 | 1900 |
| Adhesion (N/mm) | 0.49 | 0.45 | 0.46 | 0.48 | 0.45 |

| | | | | | Comparative | Comparative |
|---|---|---|---|---|---|---|
| | | | Example 18 | Example 19 | Example 1 | Example 2 |
| Binder | Type | | Kuraray Poval | Kuraray Poval | Kuraray Poval | Kuraray Poval |
| | | | KL-318 | KL-318 | KL-318 | KL-318 |
| | Degree of polymerization | | 1800 | 1800 | 2400 | 2400 |
| | Amount(mass% in heat | | 8.9 | 8.9 | 8.9 | 8.9 |
| | storage sheet) | | | | | |
| Microcapsule | Particle diameter Dm (μm) | | 22 | 18.5 | 20 | 20 |
| | Wall thickness δ (μm) | | 0.15 | 0.092 | 0.2 | 0.1 |
| | δ/Dm | | 0.007 | 0.005 | 0.010 | 0.005 |
| | Deformation rate (%) | | 29 | 46 | 24 | 50 |
| Protective layer | | | Absence | Absence | Absence | Absence |
| Drying | Drying temperature | | 80 | 100 | 80 | 30 |
| condition | Drying time | | 25 | 15 | 25 | 180 |
| (heat | | | | | | |
| storage sheet) | | | | | | |
| Evaluation | Void volume (% by volume) | | 9.7 | 0.5 | 18.0 | 23.0 |
| result | Adjacency ratio (%) | | 85.3 | 97.2 | 70.6 | 60.7 |
| | Latent heat | (J/g) | 199 | 203 | 203 | 203 |
| | capacity (only | (J/ml) | 166 | 181 | 151 | 142 |
| | heat storage sheet | | | | | |
| | portion) | | | | | |
| | Latent heat | (J/g) | 190 | 195 | 194 | 193 |
| | capacity (entire | (J/ml) | 151 | 170 | 142 | 134 |
| | member) | | | | | |

| | | | | |
|---|---|---|---|---|
| Defect | 2 | 1 | 3 | 3 |
| Modulus of elasticity (MPa) | 1800 | 4500 | 1667 | 1458 |
| Adhesion (N/mm) | 0.44 | 0.51 | 0.43 | 0.41 |

As shown in Table 1 and Table 2, as compared with a case in which the heat storage sheet having the void volume of 10% by volume or more was used (Comparative Example 1 and Comparative Example 2), in a case in which the heat storage sheet having the void volume of less than 10% by volume was used (Examples 1 to 19), it was confirmed that the occurrence of defects when handling it can be suppressed, and the adhesion of the heat storage member including the heat storage sheet was excellent.

Also, as shown in Table 1 and Table 2, as compared with a case in which the heat storage sheet having the adjacency ratio of less than 80% or more was used (Comparative Example 1 and Comparative Example 2), in a case in which the heat storage sheet having the adjacency ratio of 80% or more was used (Examples 1 to 19), it was confirmed that the occurrence of defects when handling it can be suppressed, and the adhesion of the heat storage member including the heat storage sheet was excellent.

Regarding the heat storage members which were manufactured in Examples 1 to 19, in a case in which the pressure sensitive adhesive layer of the PET base material (A) with the easily adhesive layer and the pressure sensitive adhesive layer adhered to a metal cover surface of the CPU, and it was confirmed that the heat storage sheet surface did not become hot even in a case in which the CPU generates heat.

Further, it was confirmed that the heat generation of the CPU can be suppressed even in a case in which the heat storage members manufactured in Examples 1 to 19 were brought into contact with one end of the heat pipe and the other end of the heat pipe was brought into contact with the CPU.

The heat storage member was manufactured in the same manner as in Example 1 except that n-icosane was changed to n-heptadecane (aliphatic hydrocarbon having a melting point of 22° C. and 17 carbon atoms), the pressure sensitive adhesive layer of the PET base material (A) with the easily adhesive layer and the pressure sensitive adhesive layer adhered to the lithium-ion battery, and tested in the same manner as above. As a result, it was confirmed that the temperature of the surface of the heat storage sheet did not easily become hot even in a case in which the battery generated heat.

Eight types of the heat storage members were manufactured in the same manner as in Example 1 by changing n-icosane to each of n-octadecane (aliphatic hydrocarbon having a melting point of 28° C. and 18 carbon atoms), n-nonadecane (aliphatic hydrocarbon having a melting point of 32° C. and 19 carbon atoms), n-henicosane (aliphatic hydrocarbon having a melting point of 40° C. and 21 carbon atoms), n-docosane (aliphatic hydrocarbon having a melting point of 44° C. and 22 carbon atoms), n-tricosane (aliphatic hydrocarbon having a melting point of 49° C. and 23 carbon atoms), n-tetracosane (aliphatic hydrocarbon having a melting point of 52° C. and 24 carbon atoms), n-pentacosane (aliphatic hydrocarbon having a melting point of 54° C. and 25 carbon atoms), and n-hexacosane (aliphatic hydrocarbon having a melting point of 60° C. and 26 carbon atoms). In a case in which the pressure sensitive adhesive layer of the PET base material (A) with the easily adhesive layer and the pressure sensitive adhesive layer adhered to the metal cover surface of the CPU and tested in the same manner as above, it was confirmed that the surface of the heat storage sheet did not easily become hot even in a case in which the CPU generated heat.

What is claimed is:

1. A heat storage sheet comprising a microcapsule which encapsulates a heat storage material,
wherein a void volume is less than 10% by volume.

2. The heat storage sheet according to claim 1,
wherein the void volume is 5% by volume or less.

3. The heat storage sheet according to claim 1,
wherein an adjacency ratio of the microcapsule is 80% or more.

4. A heat storage sheet comprising a microcapsule which encapsulates a heat storage material,
wherein an adjacency ratio of the microcapsule is 80% or more.

5. The heat storage sheet according to claim 1,
wherein the heat storage material includes linear aliphatic hydrocarbon, and
a content of the linear aliphatic hydrocarbon to a total mass of the heat storage material is 98% by mass or more.

6. The heat storage sheet according to claim 1,
wherein a content of the heat storage material to a total mass of the heat storage sheet is 50% by mass or more.

7. The heat storage sheet according to claim 1,
wherein a capsule wall of the microcapsule is formed of polyurethane urea.

8. The heat storage sheet according to claim 1,
wherein a ratio of a thickness of a capsule wall of the microcapsule to a volume-based median diameter of the microcapsule is 0.0075 or less.

9. The heat storage sheet according to claim 1,
wherein a thickness of a capsule wall of the microcapsule is 0.15 μm or less.

10. The heat storage sheet according to claim 1,
wherein a deformation rate of the microcapsule is 35% or more.

11. The heat storage sheet according to claim 1,
wherein a content of water to a total mass of the heat storage sheet is 5% by mass or less.

12. The heat storage sheet according to claim 1, further comprising a binder.

13. The heat storage sheet according to claim 12,
wherein the binder includes a water-soluble polymer, and
a content of the water-soluble polymer to a total mass of the binder is 90% by mass or more.

14. The heat storage sheet according to claim 13,
wherein the water-soluble polymer is polyvinyl alcohol.

15. The heat storage sheet according to claim 14,
wherein the polyvinyl alcohol has a modified group.

16. The heat storage sheet according to claim 15,
wherein the modified group is at least one group selected from the group consisting of a carboxy group or a salt thereof and an acetoacetyl group.

17. A heat storage member comprising the heat storage sheet according to claim 1.

18. The heat storage member according to claim 17, further comprising:
a base material which is disposed on the heat storage sheet;
an adhesion layer which is disposed on a surface side of the base material opposite to the heat storage sheet; and
a temporary base material which is disposed on a surface side of the adhesion layer opposite to the base material.

19. An electronic device comprising:
the heat storage member according to claim 17; and
a heat generating body.

20. The electronic device according to claim 19, further comprising a member selected from the group consisting of a heat pipe and a vapor chamber.
